(19) United States
(12) Patent Application Publication
(10) Pub. No.: US 2016/0043317 A1
(43) Pub. Date: Feb. 11, 2016

(54) ORGANIC ELECTROLUMINESCENT DEVICE

(71) Applicant: SAMSUNG DISPLAY CO., LTD., Yongin-City (KR)

(72) Inventors: Ichinori Takada, Yokohama (JP); Yasuo Miyata, Yokohama (JP); Hiroaki Itoi, Yokohama (JP); Shuri Sato, Yokohama (JP); Ikuo Sasaki, Yokohama (JP)

(21) Appl. No.: 14/818,232

(22) Filed: Aug. 4, 2015

(30) Foreign Application Priority Data
Aug. 5, 2014 (JP) 2014-159842
Aug. 5, 2014 (JP) 2014-159844

(51) Int. Cl. H01L 51/00; H01L 51/50

(52) U.S. Cl. CPC H01L 51/006; H01L 51/5064; H01L 51/0061; H01L 51/0059; H01L 51/0072; H01L 51/5206

(57) ABSTRACT

An organic electroluminescent device may include an anode, a cathode, an emission layer between the anode and the cathode, and a laminate structure between the anode and the emission layer, the laminate structure including at least three layers. The at least three layers may include a first layer including a hole transport compound doped with an electron accepting compound having a lowest unoccupied molecular orbital (LUMO) level from about −9.0 eV to about −4.0 eV and a second layer between the first layer and the emission layer. The second layer may be adjacent to the emission layer and may include a compound represented by Formula (1). Formula (1)

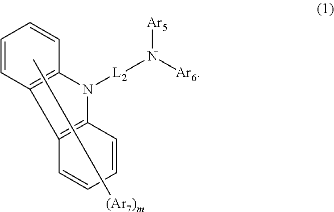

### CROSS-REFERENCE TO RELATED APPLICATIONS

This patent application claims priority to and the benefit of Japanese Patent Applications Nos. 2014-159842, filed on Aug. 5, 2014, and 2014-159844, filed on Aug. 5, 2014, the entire contents of both of which are incorporated herein by reference.

### BACKGROUND

One or more aspects of embodiments of the present disclosure relate to an organic electroluminescent device, and more particularly, to an organic electroluminescent device having high efficiency and long life.

Recently, an organic electroluminescent display (herein, “organic EL display”) is being actively developed as an image display apparatus. Unlike a liquid crystal display or the like, the organic EL display is a self luminescent type (or kind) of display, which is capable of displaying images via light emission of an organic luminescent material included in an emission layer by, for example, recombining holes and electrons respectively injected from an anode and a cathode into the emission layer to generate light.

An organic electroluminescent device (hereinafter, “organic EL device”) may include an anode, a hole transport layer on the anode, an emission layer on the hole transport layer, an electron transport layer on the emission layer, and a cathode on the electron transport layer. Holes injected from the anode pass through the hole transport layer and are injected into the emission layer. Electrons injected from the cathode pass through the electron transport layer and are injected into the emission layer. The holes and the electrons injected into the emission layer are recombined, and excitons are generated in the emission layer. The organic EL device emits light generated by the radiation deactivation of the excitons in the emission layer. The organic EL device is not limited to the aforementioned configuration, and may include modifications thereof.

The organic EL device included in a display device is required to have high emission efficiency and long life. For example, in a blue emission region and a green emission region, the emission efficiency and the life of the organic EL device may be insufficient. To realize the high efficiency of the driving voltage of the organic EL device, the organic EL device may include a band between an anode and an emission layer, and the normalization and the stabilization with the emission layer may be employed. For example, a layer including an electron accepting material (hereinafter, also referred to as “an acceptor layer”) may be included to assist in hole transportation.

As a hole transport material used in a hole transport layer, compounds such as an anthracene derivative, an aromatic amine compound, and/or the like may be used (utilized). However, development of a novel material may be required to increase the life of the organic EL device and obtain the high efficiency of the driving voltage. For example, the organic EL device may include an amine compound combined (e.g., coupled) with a carbazole part (e.g., a carbazole moiety) via a fluorene part (e.g., a fluorene moiety) in a hole injection layer or a hole transport layer. In another example, an amine derivative with a carbazole part and a fluorene part (e.g., an amine derivative including a carbazole moiety and a fluorene moiety) may be utilized as a hole transport material. For example, an organic EL device may include an electron accepting dopant having the lowest unoccupied molecular orbital (LUMO) level from about −9.0 eV to about −4.0 eV in at least one layer selected from organic material layers positioned between an emission layer and an anode.

Referring to the relationship between the materials and the structure of an organic EL device, an organic EL device may include an amine derivative combined (e.g., coupled) with a carbazole part via a fluorene part in at least one of a plurality of organic thin layers positioned between an emission layer and an anode and further including an accepting material (e.g., 1,4,5,8,9,12-hexaazatriphenylene (HAT)) in at least one of the plurality of organic thin layers. For example, an organic EL device may be manufactured by laminating (herein, may also refer to “positioning” and/or “including”) a hole transport layer formed using an amine derivative having a carbazole part and a fluorene part positioned adjacent to an emission layer and further including a hole injection layer having a three-layered structure between an anode and the hole transport layer. The hole injection layer may include: (1) a layer including a diamine derivative in which each carbazole part is combined (e.g., coupled) with two nitrogen atoms, respectively, (2) a layer including a diamine derivative in which each carbazole part is combined (e.g., coupled) with two nitrogen atoms, respectively, and an amine derivative in which a carbazole part and a fluorine part are combined (e.g., coupled) with a nitrogen atom, and (3) a layer including HAT, positioned on the anode in the stated order. For example, an organic EL device may have a repeating structure (e.g., a structure including multiple combinations) of (1) a layer including an amine derivative having a carbazole part and a fluorene part, (2) a layer including an amine derivative having a HAT-doped carbazole part and a fluorene part, and (3) a layer including an amine derivative having a carbazole part and a fluorene part, positioned between an anode and an emission layer, wherein the layer including the amine derivative having the carbazole part and the fluorene part is adjacent to the emission layer.

In one example, a diamine compound having the above-described structure may be used as a first hole transport layer material, and an aromatic amine derivative with a terphenyl structure and a carbazole structure (e.g., an aromatic amine derivative including a terphenyl moiety and a carbazole moiety) may be used as a second hole transport material. As another example, the above-described electron accepting compound may be used, and an aromatic amine derivative with a terphenyl amine structure and a carbazole structure (e.g., an aromatic amine derivative including a terphenyl amine moiety and a carbazole moiety) may be used as a first hole transport material. In addition, a first hole transport layer may include triphenylene as an electron accepting compound.

### SUMMARY

While examination of the materials for forming the aforementioned layers of an organic EL device has been conducted; the configuration of the device has not been thoroughly examined. In addition, methods for manufacturing an organic EL device that are generally available in the art may be insufficient to realize an organic EL device having high efficiency and long life.

One or more aspects of embodiments of the present disclosure are directed toward an organic EL device which may be driven at a low voltage and have high efficiency and long life.

In one or more embodiments of the present disclosure, an organic EL device includes an anode, a cathode, an emission layer between the anode and the cathode, and a laminate structure between the anode and the emission layer, the laminate structure including at least three layers, the at least three layers including a first layer including a hole transport compound doped with an electron accepting compound having a LUMO level from about −9.0 eV to about −4.0 eV, and a second layer between the first layer and the emission layer. The second layer may be adjacent to the emission layer and may include a compound represented by Formula (1):

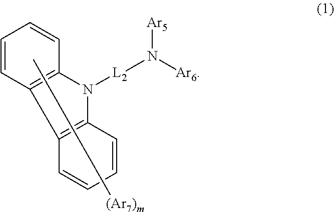

In Formula (1), Ar₅, Ar₆ and Ar₇ may each independently be selected from a substituted or unsubstituted aryl group having 6 to 30 carbon atoms for forming a ring, a substituted or unsubstituted heteroaryl group having 3 to 30 carbon atoms for forming a ring, an alkyl group having 1 to 10 carbon atoms, and an alkenyl group having 1 to 10 carbon atoms; L₂ may be a substituted or unsubstituted fluorenediyl group; and m may be an integer from 0 to 8. When m is 2 or more, a plurality of Ar₇ may be the same as or different from each other, and adjacent Ar₇s may be combined to each other to form a ring shaped structure (e.g., a ring).

In the organic EL device according to embodiments of the present disclosure, hole injection properties of the anode (e.g., hole injection from the anode) may be improved, the laminate structure (herein, also referred to as the “hole transport laminate structure”) may be passivated from electrons not consumed in the emission layer, the diffusion of energy with an excited state (e.g., the diffusion of excitons) generated in the emission layer into the hole transport laminate structure may be prevented or reduced, and the charge balance of the organic EL device may be controlled, thereby realizing the organic EL device having high emission efficiency and long life.

In some embodiments, the at least three layers may further include a third layer between the anode and the second layer, the third layer including a compound represented by Formula (2):

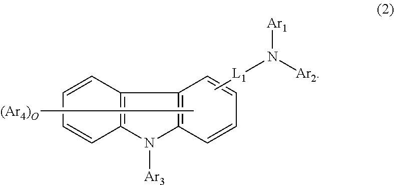

In Formula (2), Ar₁, Ar₂ and Ar₃ may each independently be selected from a substituted or unsubstituted aryl group having 6 to 30 carbon atoms for forming a ring, a substituted or unsubstituted heteroaryl group having 3 to 30 carbon atoms for forming a ring, an alkyl group having 1 to 10 carbon atoms, and an alkenyl group having 1 to 10 carbon atoms; Ar₄ may be selected from a substituted or unsubstituted aryl group having 6 to 30 carbon atoms for forming a ring, a substituted or unsubstituted heteroaryl group having 3 to 30 carbon atoms for forming a ring, an alkyl group having 1 to 10 carbon atoms, an alkenyl group having 1 to 10 carbon atoms, a deuterium atom, and a halogen atom; L₁ may be selected from a direct linkage, a substituted or unsubstituted arylene group having 6 to 30 carbon atoms for forming a ring, a heteroarylene group having 3 to 30 carbon atoms for forming a ring, and an alkylene group having 1 to 10 carbon atoms; and o may be an integer from 0 to 7. When o is 2 or more, a plurality of Ar₄ may be the same as or different from each other, and adjacent Ar₄s may be combined to each other to form a ring shaped structure.

When the organic EL device according to embodiments of the present disclosure includes a compound having a carbazolyl group (e.g., the compound represented by Formula (1) and/or the compound represented by Formula (2)) in the hole transport laminate structure, hole transport properties and current flowing durability may be improved, thereby realizing the organic EL device having high emission efficiency and long life.

In some embodiments, the hole transport compound in the first layer of the organic EL device according to embodiments of the present disclosure may include the compound represented by Formula (2).

When the organic EL device according to embodiments of the present disclosure includes a compound having a carbazolyl group (e.g., the compound represented by Formula (1) and/or the compound represented by Formula (2)) in the hole transport laminate structure, hole transport properties and current flowing durability may be improved, thereby realizing the organic EL device having high emission efficiency and long life.

In the organic EL device according to embodiments of the present disclosure, the hole transport laminate structure may be passivated from electrons not consumed in an emission layer, the diffusion of energy with an excited state (e.g., the diffusion of excitons) generated in the emission layer into the hole transport laminate structure may be prevented or reduced, and the charge balance of the organic EL device may be controlled, thereby realizing the organic EL device having high emission efficiency and long life.

In some embodiments, the emission layer may include a compound represented by Formula (3):

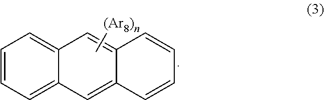

In Formula (3), each Ar₈ may be independently selected from a hydrogen atom, a deuterium atom, a substituted or unsubstituted aryl group having 6 to 30 carbon atoms for forming a ring, a substituted or unsubstituted heteroaryl group having 3 to 30 carbon atoms for forming a ring, and an alkyl group having 1 to 10 carbon atoms; and n may be an integer from 1 to 10.

In some embodiments, the emission layer of the organic EL device may be configured to facilitate luminescence via a singlet excited state.

In some embodiments of the present disclosure, an organic EL device may include an anode, a cathode, an emission layer between the anode and the cathode, and a laminate structure between the anode and the emission layer, the laminate structure including at least three layers, the at least three layers including a first layer including an electron accepting compound having a LUMO level from about −9.0 eV to about −4.0 eV as a main component and a second layer between the first layer and the emission layer. The second layer may be adjacent to the emission layer and may include a compound represented by Formula (1):

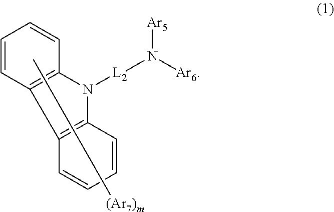

In Formula (1), Ar₅, Ar₆ and Ar₇ may each independently be selected from a substituted or unsubstituted aryl group having 6 to 30 carbon atoms for forming a ring, a substituted or unsubstituted heteroaryl group having 3 to 30 carbon atoms for forming a ring, an alkyl group having 1 to 10 carbon atoms, and an alkenyl group having 1 to 10 carbon atoms; L₂ may be a substituted or unsubstituted fluorenediyl group; and m may be an integer from 0 to 8.

In some embodiments, the at least three layers may further include a third layer between the first layer and the second layer, the third layer including a compound represented by Formula (2):

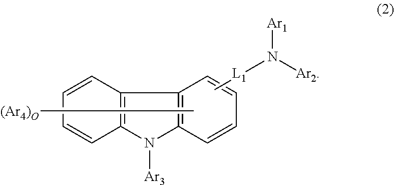

In Formula (2), Ar₁, Ar₂ and Ar₃ may each independently be selected from a substituted or unsubstituted aryl group having 6 to 30 carbon atoms for forming a ring, a substituted or unsubstituted heteroaryl group having 3 to 30 carbon atoms for forming a ring, an alkyl group having 1 to 10 carbon atoms, and an alkenyl group having 1 to 10 carbon atoms; Ar₄ may be selected from a substituted or unsubstituted aryl group having 6 to 30 carbon atoms for forming a ring, a substituted or unsubstituted heteroaryl group having 3 to 30 carbon atoms for forming a ring, an alkyl group having 1 to 10 carbon atoms, an alkenyl group having 1 to 10 carbon atoms, a deuterium atom, and a halogen atom; L₁ may be selected from a direct linkage, a substituted or unsubstituted arylene group having 6 to 30 carbon atoms for forming a ring, a heteroarylene group having 3 to 30 carbon atoms for forming a ring, and an alkylene group having 1 to 10 carbon atoms; and o may be an integer from 0 to 7.

In some embodiments, the emission layer may include a compound represented by Formula (3):

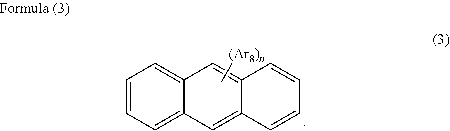

In Formula (3), each Ar₈ may be independently selected from a hydrogen atom, a deuterium atom, a substituted or unsubstituted aryl group having 6 to 30 carbon atoms for forming a ring, a substituted or unsubstituted heteroaryl group having 3 to 30 carbon atoms for forming a ring, and an alkyl group having 1 to 10 carbon atoms; and n may be an integer from 1 to 10.

The organic EL device according to embodiments of the present disclosure may have improved emission efficiency and long life.

According to one or more aspects of embodiments of the present disclosure, an organic EL device having high efficiency and long life may be provided.

### BRIEF DESCRIPTION OF THE FIGURES

The accompanying drawings are included to provide a further understanding of the present disclosure, and are incorporated in and constitute a part of this specification. The drawings illustrate example embodiments of the present disclosure and, together with the description, serve to explain principles of the present disclosure. In the drawings:

FIG. 1 is a schematic diagram illustrating an organic EL device 100 according to one or more embodiments of the present disclosure; and

FIG. 2 is a schematic diagram illustrating an organic EL device 200 according to one or more embodiments of the present disclosure.

### DETAILED DESCRIPTION

According to one or more aspects of embodiments of the present disclosure, hole injection properties of an anode (e.g., hole injection from an anode) in an organic EL device could be improved by placing an acceptor layer (e.g., a layer including an electron accepting material) adjacent to the anode. According to embodiments of the present disclosure, a laminated layer having hole transport properties may be positioned between an emission layer and an anode and includes at least a layer including a hole transport compound doped with an electron accepting material laminated adjacent to the anode and a layer including an amine derivative including a carbazolyl group laminated adjacent to the emission layer.

Hereinafter, the organic EL device according to one or more embodiments of the present disclosure will be described in more detail with reference to the accompanying drawings. The organic EL device of the present disclosure may, however, be embodied in different forms and should not be construed as limited to the embodiments set forth herein. In the drawings, like reference numerals refer to like elements or elements having like functions throughout, and duplicative descriptions thereof will not be provided.

1-1. Organic EL Device Including First Layer Including Hole Transport Compound Doped with Electron Accepting Material

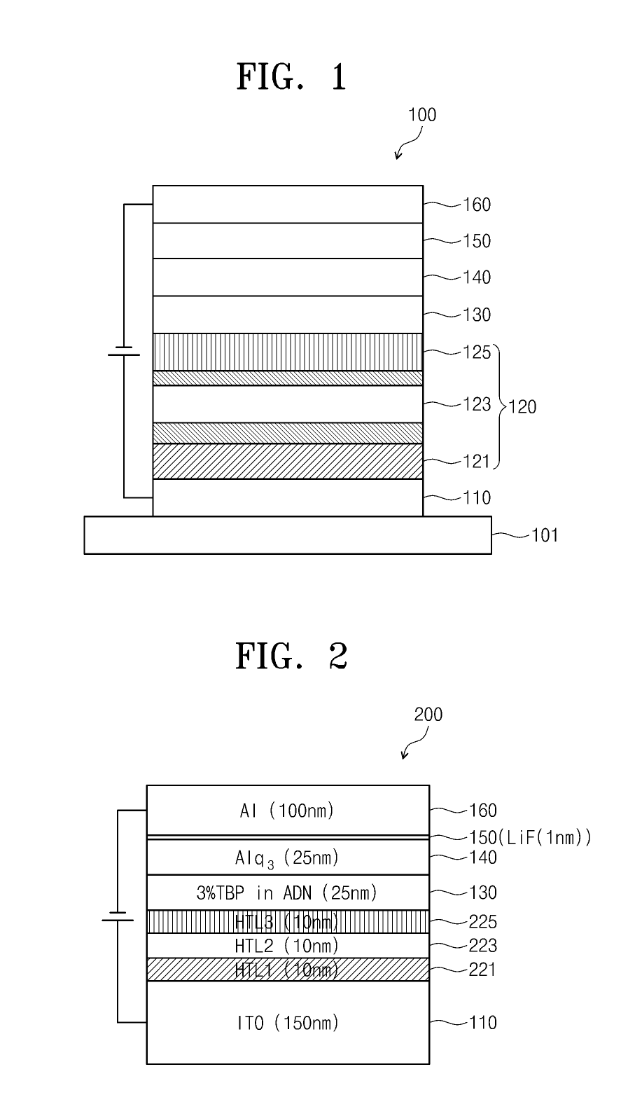

The organic EL device according to embodiments of the present disclosure will be explained with reference to FIG. 1. FIG. 1 is a schematic diagram illustrating an organic EL device 100 according to embodiments of the present disclosure. The organic EL device 100 may include, for example, a substrate 101, and an anode 110, an emission layer 130, an electron transport layer 140, an electron injection layer 150, and a cathode 160 positioned on the substrate 101. Between the anode 110 and the emission layer 130, a hole transport band 120 may be positioned. The hole transport band 120 may include a hole transport layer, a hole injection layer, and/or the like.

In embodiments of the present disclosure, to realize an organic EL device having improved emission efficiency and long life, a laminate structure (herein, also referred to as “a hole transport laminate structure”, or “integrated structure”) including at least three layers having different components (e.g., having different compositions) may be positioned in the hole transport band 120 between the anode 110 and the emission layer 130. The laminate structure may include at least a first layer 121 (herein, also referred to as “a hole injection layer”) and a second layer 125 (herein, also referred to as “an intermediate layer”). At least one layer of the laminate structure (e.g., the first layer 121) may be positioned adjacent to the anode 110 and may include a hole transport compound doped with an electron accepting compound having a lowest occupied molecular orbital (LUMO) level from about −9.0 eV to about −4.0 eV. At least one layer of the laminate structure (e.g., the second layer 125) may be positioned between the first layer 121 and the emission layer 130, adjacent to the emission layer 130, and may include a compound represented by Formula (1).

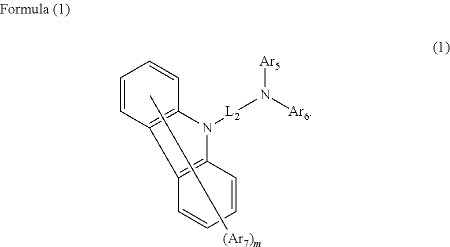

In Formula (1), Ar₅, Ar₆ and Ar₇ may each independently be selected from a substituted or unsubstituted aryl group having 6 to 30 carbon atoms for forming a ring, a substituted or unsubstituted heteroaryl group having 3 to 30 carbon atoms for forming a ring, an alkyl group having 1 to 10 carbon atoms, and an alkenyl group having 1 to 10 carbon atoms; and L₂ may be a substituted or unsubstituted fluorenediyl group. As used herein, the statement “atoms for forming a ring” may refer to “ring-forming atoms.” In Formula (1), m may be an integer from 0 to 8. When m is 2 or more-, a plurality of Ar₇ may be the same as or different from each other. In some embodiments, when m is 2 or more, adjacent Ar₇s may be combined (e.g., coupled) to each other to form a ring shaped structure (e.g., a ring).

Non-limiting examples of Ar₅, Ar₆ and/or Ar₇ may include a phenyl group, a biphenyl group, a terphenyl group, a naphthyl group, an anthryl group, a phenanthryl group, a fluorenyl group, an indenyl group, a pyrenyl group, an acetonaphthenyl group, a fluoranthenyl group, a triphenylenyl group, a pyridyl group, a furanyl group, a pyranyl group, a thienyl group, a quinolyl group, an isoquinolyl group, a benzofuranyl group, a benzothienyl group, an indolyl group, a carbazolyl group, a benzoxazolyl group, a benzothiazolyl group, a quinoxalyl group, a benzoimidazolyl group, a pyrazolyl group, a dibenzofuranyl group, a dibenzothienyl group, and the like. In some embodiments, Ar₅, Ar₆ and Ar₇ may each independently be selected from the phenyl group, the biphenyl group, the terphenyl group, the fluorenyl group, the carbazolyl group, the dibenzofuranyl group, and the like.

The compound represented by Formula (1) may be represented by one of Compounds 1 to 15. In the formulae for Compounds 1 to 15, the symbol “Me” refers to a methyl group. However, the compound represented by Formula (1) is not limited thereto.

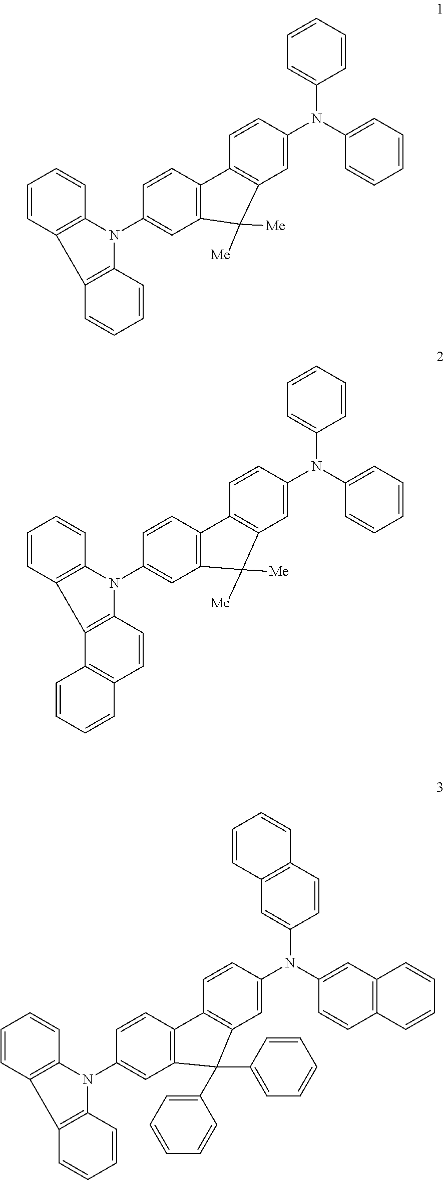 [SMILES: CC1(C)c2cc(N(c3ccccc3)c3ccccc3)ccc2-c2ccc(-n3c4ccccc4c4ccccc43)cc21 ; CC1(C)c2cc(N(c3ccccc3)c3ccccc3)ccc2-c2ccc(-n3c4ccccc4c4c5ccccc5ccc43)cc21 ; c1ccc(C2(c3ccccc3)c3cc(N(c4ccc5ccccc5c4)c4ccc5ccccc5c4)ccc3-c3ccc(-n4c5ccccc5c5ccccc54)cc32)cc1]

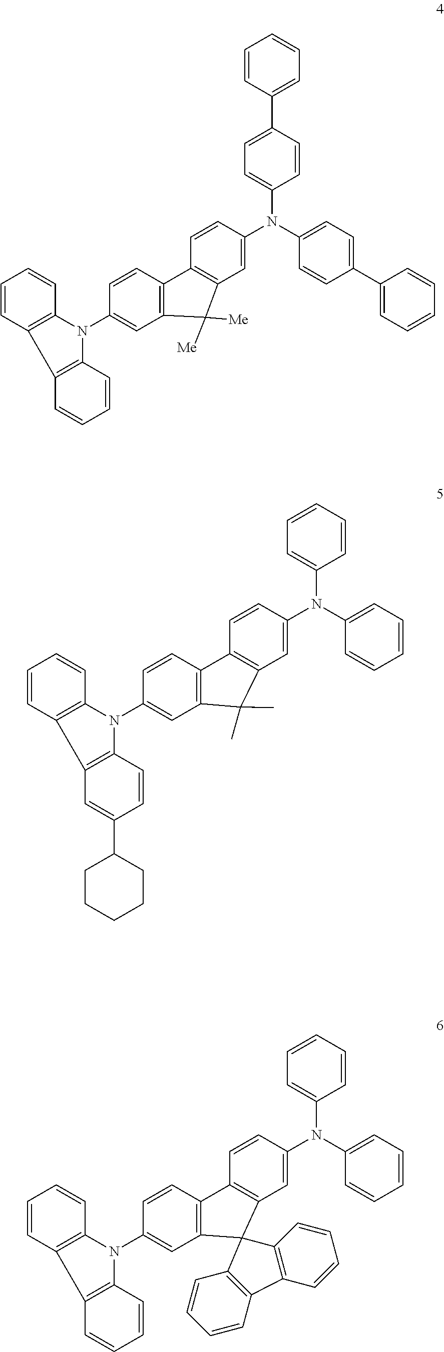 [SMILES: CC1(C)c2cc(N(c3ccc(-c4ccccc4)cc3)c3ccc(-c4ccccc4)cc3)ccc2-c2ccc(-n3c4ccccc4c4ccccc43)cc21 ; CC1(C)c2cc(N(c3ccccc3)c3ccccc3)ccc2-c2ccc(-n3c4ccccc4c4cc(C5CCCCC5)ccc43)cc21 ; c1ccc(N(c2ccccc2)c2ccc3c(c2)C2(c4ccccc4-c4ccccc42)c2cc(-n4c5ccccc5c5ccccc54)ccc2-3)cc1]

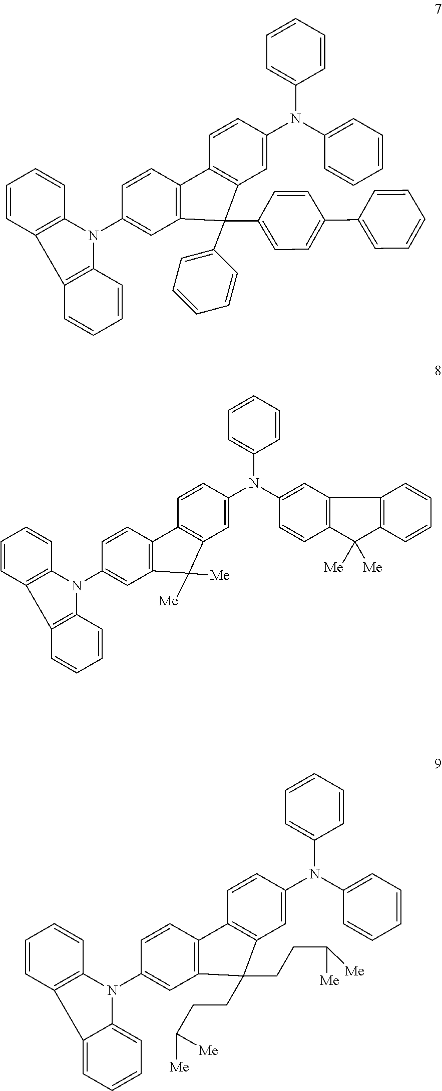 [SMILES: c1ccc(-c2ccc(C3(c4ccccc4)c4cc(N(c5ccccc5)c5ccccc5)ccc4-c4ccc(-n5c6ccccc6c6ccccc65)cc43)cc2)cc1 ; CC1(C)c2ccccc2-c2cc(N(c3ccccc3)c3ccc4c(c3)C(C)(C)c3cc(-n5c6ccccc6c6ccccc65)ccc3-4)ccc21 ; CC(C)CCC1(CCC(C)C)c2cc(N(c3ccccc3)c3ccccc3)ccc2-c2ccc(-n3c4ccccc4c4ccccc43)cc21]

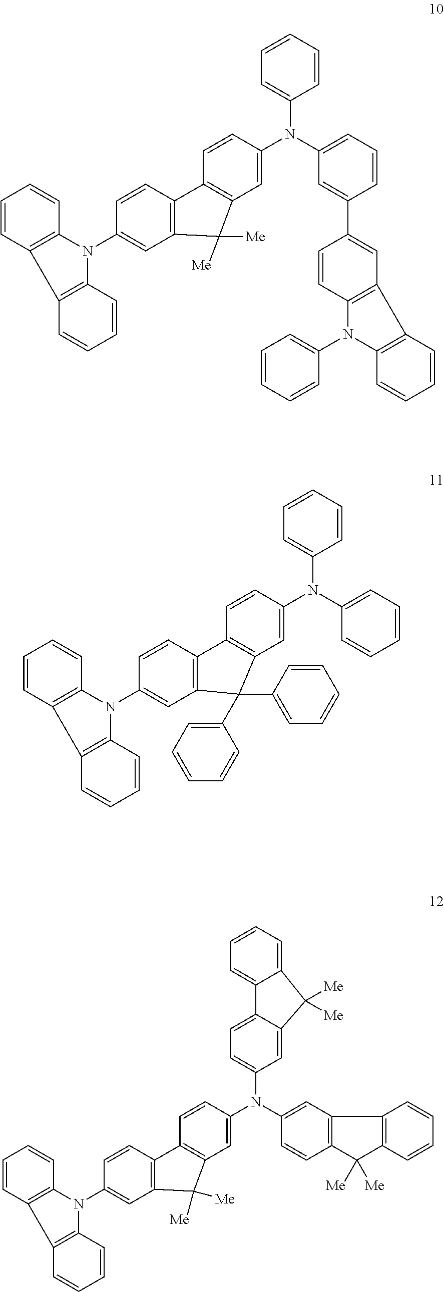 [SMILES: CC1(C)c2cc(N(c3ccccc3)c3cccc(-c4ccc5c(c4)c4ccccc4n5-c4ccccc4)c3)ccc2-c2ccc(-n3c4ccccc4c4ccccc43)cc21 ; c1ccc(N(c2ccccc2)c2ccc3c(c2)C(c2ccccc2)(c2ccccc2)c2cc(-n4c5ccccc5c5ccccc54)ccc2-3)cc1 ; CC1(C)c2ccccc2-c2cc(N(c3ccc4c(c3)C(C)(C)c3ccccc3-4)c3ccc4c(c3)C(C)(C)c3cc(-n5c6ccccc6c6ccccc65)ccc3-4)ccc21]

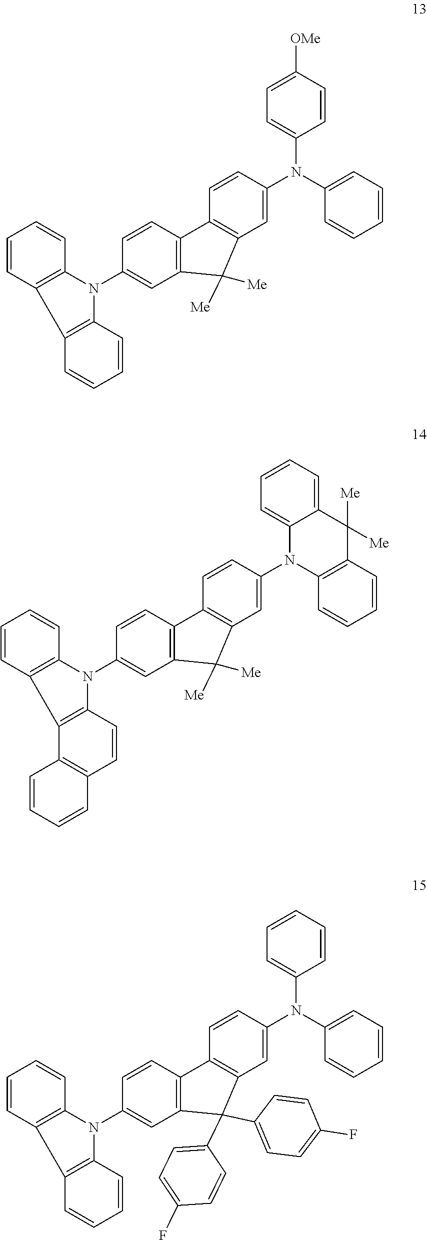 [SMILES: COc1ccc(N(c2ccccc2)c2ccc3c(c2)C(C)(C)c2cc(-n4c5ccccc5c5ccccc54)ccc2-3)cc1 ; CC1(C)c2cc(N3c4ccccc4C(C)(C)c4ccccc43)ccc2-c2ccc(-n3c4ccccc4c4c5ccccc5ccc43)cc21 ; Fc1ccc(C2(c3ccc(F)cc3)c3cc(N(c4ccccc4)c4ccccc4)ccc3-c3ccc(-n4c5ccccc5c5ccccc54)cc32)cc1]

At least one layer of the laminate structure (e.g., the first layer 121) may be positioned adjacent to the anode 110 and may include a hole transport compound doped with an electron accepting compound having a LUMO level from about −9.0 eV to about −4.0 eV. Non-limiting examples of the electron accepting compound doped into the first layer 121 may be compounds represented by Formulae ac1 to ac14. However, the electron accepting compound according to embodiments of the present disclosure is not limited thereto. In some embodiments, the amount doped (herein, also referred to as “the doping amount) of the electron accepting compound may be from about 0.1 wt % to about 50 wt % based on the total amount of the hole transport compound, and in some embodiments, may be from about 0.5 wt % to about 5 wt %.

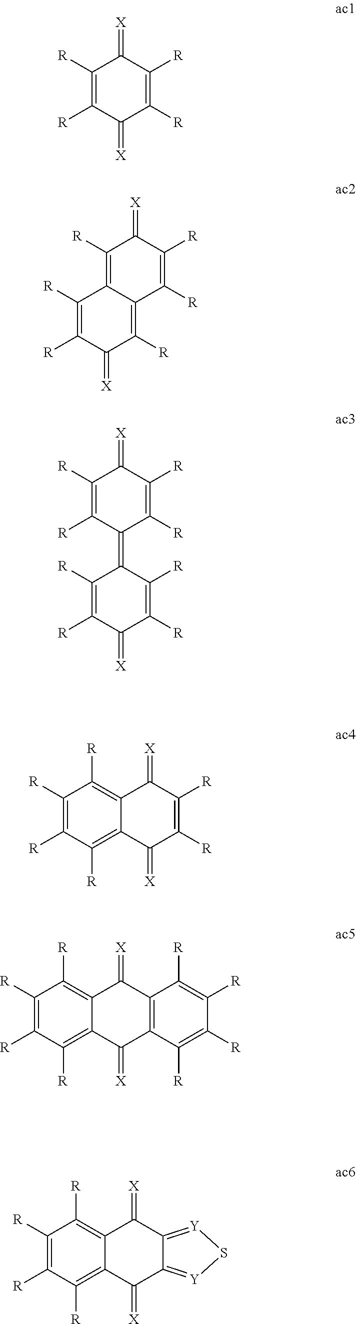

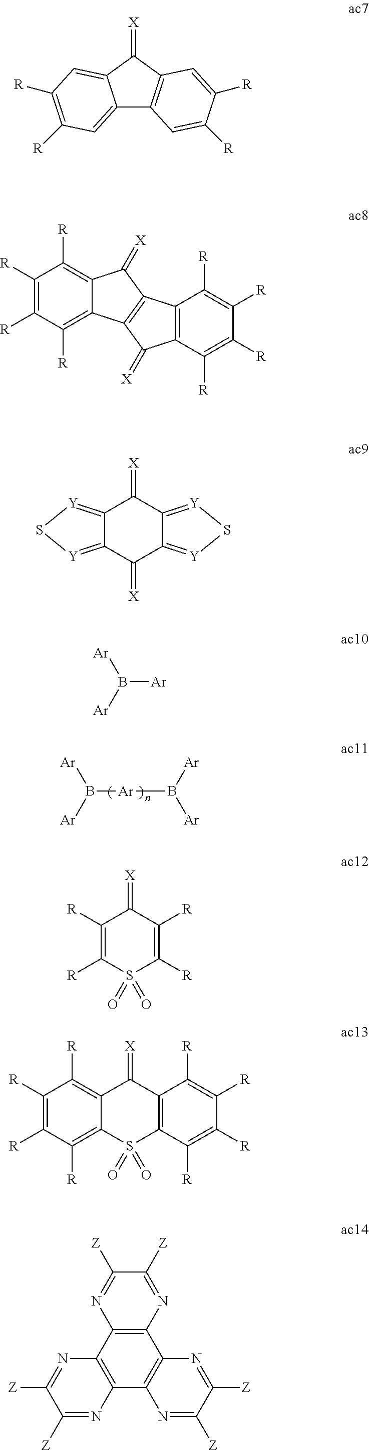

In Formulae ac1 to ac14, R may be selected from a hydrogen atom, a deuterium atom, a halogen atom, a fluoroalkyl group having 1 to 10 carbon atoms, a cyano group, an alkoxy group having 1 to 10 carbon atoms, an alkyl group having 1 to 10 carbon atoms, and a substituted or unsubstituted aryl group having 6 to 30 carbon atoms for forming a ring, and the Rs included in the same compound are not all hydrogen atoms, deuterium atoms, or fluorine atoms. Each Ar may independently be a substituted or unsubstituted electron withdrawing aryl group having 6 to 30 carbon atoms for forming a ring or a substituted or unsubstituted heteroaryl group having 3 to 30 carbon atoms for forming a ring. Y may be a methine group (—CH═) or a group including a nitrogen atom (—N═). Z may be pseudohalogen (e.g., a pseudohalogen group) or may include sulfur (S) (e.g., Z may be a sulfur-containing group). X may be selected from the groups X1 to X7.

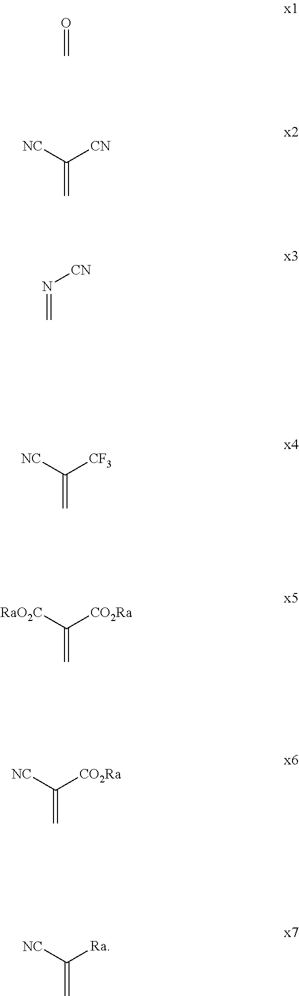

In groups X1 to X7, Ra may be selected from a hydrogen atom, a deuterium atom, a halogen atom, a fluoroalkyl group having 1 to 10 carbon atoms, a cyano group, an alkoxy group having 1 to 10 carbon atoms, an alkyl group having 1 to 10 carbon atoms, a substituted or unsubstituted aryl group having 6 to 30 carbon atoms for forming a ring, and a substituted or unsubstituted heteroaryl group having 3 to 30 carbon atoms for forming a ring.

Non-limiting examples of the substituted or unsubstituted aryl group having 6 to 30 carbon atoms for forming a ring and the substituted or unsubstituted heteroaryl group having 3 to 30 carbon atoms for forming a ring, represented by R, Ar and/or Ra, may include a phenyl group, a 1-naphthyl group, a 2-naphthyl group, a 1-anthryl group, a 2-anthryl group, a 9-anthryl group, a 1-phenanthryl group, a 2-phenanthryl group, a 3-phenanthryl group, a 4-phenanthryl group, a 9-phenanthryl group, a 1-naphthacenyl group, a 2-naphthacenyl group, a 9-naphthacenyl group, a 1-pyrenyl group, a 2-pyrenyl group, a 4-pyrenyl group, a 2-biphenylyl group, a 3-biphenylyl group, a 4-biphenylyl group, a p-terphenyl-4-yl group, a p-terphenyl-3-yl group, a p-terphenyl-2-yl group, a m-terphenyl-4-yl group, a m-terphenyl-3-yl group, a m-terphenyl-2-yl group, an o-tolyl group, a m-tolyl group, a p-tolyl group, a p-t-butylphenyl group, a p-(2-phenylpropyl)phenyl group, a 3-methyl-2-naphthyl group, a 4-methyl-1-naphthyl group, a 4-methyl-1-anthryl group, a 4′-methylbiphenylyl group, a 4″-t-butyl-p-terphenyl-4-yl group, a fluoranthenyl group, a fluorenyl group, a 1-pyrrolyl group, a 2-pyrrolyl group, a 3-pyrrolyl group, a pyridinyl group, a 2-pyridinyl group, a 3-pyridinyl group, a 4-pyridinyl group, a 1-indolyl group, a 2-indolyl group, a 3-indolyl group, a 4-indolyl group, a 5-indolyl group, a 6-indolyl group, a 7-indolyl group, a 1-isoindolyl group, a 2-isoindolyl group, a 3-isoindolyl group, a 4-isoindolyl group, a 5-isoindolyl group, a 6-isoindolyl group, a 7-isoindolyl group, a 2-furyl group, a 3-furyl group, a 2-benzofuranyl group, a 3-benzofuranyl group, a 4-benzofuranyl group, a 5-benzofuranyl group, a 6-bnzofuranyl group, a 7-benzofuranyl group, a 1-isobenzofuranyl group, a 3-isobenzofuranyl group, a 4-isobenzofuranyl group, a 5-isobenzofuranyl group, a 6-isobenzofuranyl group, a 7-isobenzofuranyl group, a quinolyl group, a 3-quinolyl group, a 4-quinolyl group, a 5-quinolyl group, a 6-quinolyl group, a 7-quinolyl group a 8-quinolyl group, a 1-isoquinolyl group, a 3-isoquinolyl group, a 4-isoquinolyl group, a 5-isoquinolyl group, a 6-isoquinolyl group, a 7-isoquinolyl group, a 8-isoquinolyl group, a 2-quinoxalinyl group, a 5-quinoxalinyl group, a 6-quinoxalinyl group, a 1-carbazolyl group, a 2-carbazolyl group, a 3-carbazolyl group, a 4-carbazolyl group, a 9-carbazolyl group, a 1-phenanthridinyl group, a 2-phenanthridinyl group, a 3-phenanthridinyl group, a 4-phenanthridinyl group, a 6-phenanthridinyl group, a 7-phenanthridinyl group, a 8-phenanthridinyl group, a 9-phenanthridinyl group, a 10-phenanthridinyl group, a 1-acridinyl group, a 2-acridinyl group, a 3-acridinyl group, a 4-acridinyl group, a 9-acridinyl group, a 1,7-phenanthroline-2-yl group, a 1,7-phenanthroline-3-yl group, a 1,7-phenanthroline-4-yl group, a 1,7-phenanthroline-5-yl group, a 1,7-phenanthroline-6-yl group, a 1,7-phenanthroline-8-yl group, a 1,7-phenanthroline-9-yl group, a 1,7-phenanthroline-10-yl group, a 1,8-phenanthroline-2-yl group, a 1,8-phenanthroline-3-yl group, a 1,8-phenanthroline-4-yl group, a 1,8-phenanthroline-5-yl group, a 1,8-phenanthroline-6-yl group, a 1,8-phenanthroline-7-yl group, a 1,8-phenanthroline-9-yl group, a 1,8-phenanthroline-10-yl group, a 1,9-phenanthroline-2-yl group, a 1,9-phenanthroline-3-yl group, a 1,9-phenanthroline-4-yl group, a 1,9-phenanthroline-5-yl group, a 1,9-phenanthroline-6-yl group, a 1,9-phenanthroline-7-yl group, a 1,9-phenanthroline-8-yl group, a 1,9-phenanthroline-10-yl group, a 1,10-phenanthroline-2-yl group, a 1,10-phenanthroline-3-yl group, a 1,10-phenanthroline-4-yl group, a 1,10-phenanthroline-5-ylgroup, a 2,9-phenanthroline-1-yl group, a 2,9-phenanthroline-3-yl group, a 2,9-phenanthroline-4-yl group, a 2,9-phenanthroline-5-yl group, a 2,9-phenanthroline-6-ylgroup, a 2,9-phenanthroline-7-yl group, a 2,9-phenanthroline-8-yl group, a 2,9-phenanthroline-10-yl group, a 2,8-phenanthroline-1-yl group, a 2,8-phenanthroline-3-ylgroup, a 2,8-phenanthroline-4-yl group, a 2,8-phenanthroline-5-yl group, a 2,8-phenanthroline-6-yl group, a 2,8-phenanthroline-7-yl group, a 2,8-phenanthroline-9-ylgroup, a 2,8-phenanthroline-10-yl group, a 2,7-phenanthroline-1-yl group, a 2,7-phenanthroline-3-yl group, a 2,7-phenanthroline-4-yl group, a 2,7-phenanthroline-5-yl group, a 2,7-phenanthroline-6-yl group, a 2,7-phenanthroline-8-yl group, a 2,7-phenanthroline-9-yl group, a 2,7-phenanthroline-10-yl group, a 1-phenazinyl group, a 2-phenazinyl group, a 1-phenothiazinyl group, a 2-phenothiazinyl group, a 3-phenothiazinyl group, a 4-phenothiazinyl group, a 10-phenothiazinyl group, a 1-phenoxazinyl group, a 2-phenoxazinyl group, a 3-phenoxazinyl group, a 4-phenoxazinyl group, a 10-phenoxazinyl group, a 2-oxazolyl group, a 4-oxazolyl group, a 5-oxazolyl group, a 2-oxadiazolyl group, a 5-oxadiazolyl group, a 3-furazanyl group, a 2-thienyl group, a 3-thienyl group, a 2-methylpyrrole-1-yl group, a 2-methylpyrrole-3-yl group, a 2-methylpyrrole-4-yl group, a 2-methylpyrrole-5-yl group, a 3-methylpyrrole-1-yl group, a 3-methylpyrrole-2-yl group, a 3-methylpyrrole-4-yl group, a 3-methylpyrrole-5-yl group, a 2-t-butylpyrrole-4-yl group, a 3-(2-phenylpropyl)pyrrole-1-yl group, a 2-methyl-1-indolyl group, a 4-methyl-1-indolyl group, a 2-methyl-3-indolyl group, a 4-methyl-3-indolyl group, a 2-t-butyl-1-indolyl group, a 4-t-butyl-1-indolyl group, a 2-t-butyl-3-indolyl group, a 4-t-butyl-3-indolyl group, and the like.

Non-limiting examples of the fluoroalkyl group having 1 to 10 carbon atoms, represented by R and/or Ra, may include a perfluoroalkyl group (such as a trifluoromethyl group, a pentafluoroethyl group, a heptafluoropropyl group, a heptadecafluorooctane group, and/or the like), a monofluoromethyl group, a difluoromethyl group, a trifluoroethyl group, a tetrafluoropropyl group, an octafluoropentyl group, and the like.

Non-limiting examples of the alkyl group having 1 to 10 carbon atoms, represented by R and/or Ra, may include a methyl group, an ethyl group, a propyl group, an isopropyl group, a n-butyl group, a s-butyl group, an isobutyl group, a t-butyl group, a n-pentyl group, a n-hexyl group, a n-heptyl group, a n-octyl group, a hydroxymethyl group, a 1-hydroxyethyl group, a 2-hydroxyethyl group, a 2-hydroxyisobutyl group, a 1,2-dihydroxyethyl group, a 1,3-dihydroxyisopropyl group, a 2,3-dihydroxy-t-butyl group, a 1,2,3-trihydroxypropyl group, a chloromethyl group, a 1-chloroethyl group, a 2-chloroethyl group, a 2-chloroisobutyl group, a 1,2-dichloroethyl group, a 1,3-dichloroisopropyl group, a 2,3-dichloro-t-butyl group, a 1,2,3-trichloropropyl group, a bromomethyl group, a 1-bromoethyl group, a 2-bromoethyl group, a 2-bromoisobutyl group, a 1,2-dibromoethyl group, a 1,3-dibromoisopropyl group, a 2,3-dibromo-t-butyl group, a 1,2,3-tribromopropyl group, an iodomethyl group, a 1-iodoethyl group, a 2-iodoethyl group, a 2-iodoisobutyl group, a 1,2-diiodoethyl group, a 1,3-diiodoisopropyl group, a 2,3-diiodo-t-butyl group, a 1,2,3-triiodopropyl group, an aminomethyl group, a 1-aminoethyl group, a 2-aminoethyl group, a 2-aminoisobutyl group, a 1,2-diaminoethyl group, a 1,3-diaminoisopropyl group, a 2,3-diamino-t-butyl group, a 1,2,3-triaminopropyl group, a cyanomethyl group, a 1-cyanoethyl group, a 2-cyanoethyl group, a 2-cyanoisobutyl group, a 1,2-dicyanoethyl group, a 1,3-dicyanoisopropyl group, a 2,3-dicyano-t-butyl group, a 1,2,3-tricyanopropyl group, a nitromethyl group, a 1-nitroethyl group, a 2-nitroethyl group, a 2-nitroisobutyl group, a 1,2-dinitroethyl group, a 1,3-dinitroisopropyl group, a 2,3-dinitro-t-butyl group, a 1,2,3-trinitropropyl group, a cyclopropyl group, a cyclobutyl group, a cyclopentyl group, a cyclohexyl group, a 4-methylcyclohexyl group, a 1-adamantyl group, a 2-adamantyl group, a 1-norbornyl group, a 2-norbornyl group, and the like.

The alkoxy group having 1 to 10 carbon atoms, represented by R and/or Ra, may be a group represented by —OY, and non-limiting examples of Y may include a methyl group, an ethyl group, a propyl group, an isopropyl group, a n-butyl group, a s-butyl group, an isobutyl group, a t-butyl group, a n-pentyl group, a n-hexyl group, a n-heptyl group, a n-octyl group, a hydroxymethyl group, a 1-hydroxyethyl group, a 2-hydroxyethyl group, a 2-hydroxyisobutyl group, a 1,2-dihydroxyethyl group, a 1,3-dihydroxyisopropyl group, a 2,3-dihydroxy-t-butyl group, a 1,2,3-trihydroxypropyl group, a chloromethyl group, a 1-chloroethyl group, a 2-chloroethyl group, a 2-chloroisobutyl group, a 1,2-dichloroethyl group, a 1,3-dichloroisopropyl group, a 2,3-dichloro-t-butyl group, a 1,2,3-trichloropropyl group, a bromomethyl group, a 1-bromoethyl group, a 2-bromoethyl group, a 2-bromoisobutyl group, a 1,2-dibromoethyl group, a 1,3-dibromoisopropyl group, a 2,3-dibromo-t-butyl group, a 1,2,3-tribromopropyl group, an iodomethyl group, a 1-iodoethyl group, a 2-iodoethyl group, a 2-iodoisobutyl group, a 1,2-diiodoethyl group, a 1,3-diiodoisopropyl group, a 2,3-diiodo-t-butyl group, a 1,2,3-triiodopropyl group, an aminomethyl group, a 1-aminoethyl group, a 2-aminoethyl group, a 2-aminoisobutyl group, a 1,2-diaminoethyl group, a 1,3-diaminoisopropyl group, a 2,3-diamino-t-butyl group, a 1,2,3-triaminopropyl group, a cyanomethyl group, a 1-cyanoethyl group, a 2-cyanoethyl group, a 2-cyanoisobutyl group, a 1,2-dicyanoethyl group, a 1,3-dicyanoisopropyl group, a 2,3-dicyano-t-butyl group, a 1,2,3-tricyanopropyl group, a nitromethyl group, a 1-nitroethyl group, a 2-nitroethyl group, a 2-nitroisobutyl group, a 1,2-dinitroethyl group, a 1,3-dinitroisopropyl group, a 2,3-dinitro-t-butyl group, a 1,2,3-trinitropropyl group, and the like.

A halogen atom represented by R and/or Ra may be fluorine, chlorine, bromine, and/or iodine.

As the hole transport compound included in the first layer 121 of an integrated structure in the hole transport band 120 of the organic EL device 100, any suitable hole transport compound generally available in the art of display devices may be used. In some embodiments, the hole transport compound may include one or more compounds having a carbazolyl group, but is not limited thereto. In some embodiments, the hole transport compound having the carbazolyl group may be an amine derivative, for example, may be the compound represented by Formula (2).

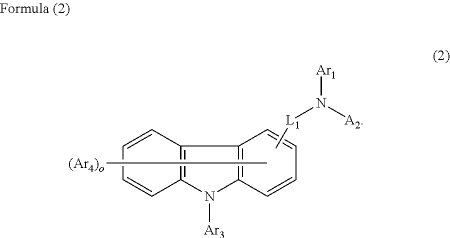

In Formula (2), Ar₁, Ar₂ and Ar₃ may each independently be selected from a substituted or unsubstituted aryl group having 6 to 30 carbon atoms for forming a ring, a substituted or unsubstituted heteroaryl group having 3 to 30 carbon atoms for forming a ring, an alkyl group having 1 to 10 carbon atoms, and an alkenyl group having 1 to 10 carbon atoms; Ar₄ may be selected from a substituted or unsubstituted aryl group having 6 to 30 carbon atoms for forming a ring, a substituted or unsubstituted heteroaryl group having 3 to 30 carbon atoms for forming a ring, an alkyl group having 1 to 10 carbon atoms, an alkenyl group having 1 to 10 carbon atoms, a deuterium atom, anda halogen atom; and L₁ may be selected from a direct linkage (e.g., a chemical bond, such as a single bond), a substituted or unsubstituted arylene group having 6 to 30 carbon atoms for forming a ring, a heteroarylene group having 3 to 30 carbon atoms for forming a ring, and an alkylene group having 1 to 10 carbon atoms. In Formula (2), o may be an integer from 0 to 7. When o is 2 or more, a plurality of Ar₄ may be the same as or different from each other. When o is 2 or more , adjacent Ar₄s may be combined (e.g., coupled) to each other to form a ring shaped structure (e.g., a ring).

Non-limiting examples of Ar₁ to Ar₄ may include a phenyl group, a biphenyl group, a terphenyl group, a naphthyl group, an anthryl group, a phenanthryl group, a fluorenyl group, an indenyl group, a pyrenyl group, an acetonaphthenyl group, a fluoranthenyl group, a triphenylenyl group, a pyridyl group, a furanyl group, a pyranyl group, a thienyl group, a quinolyl group, an isoquinolyl group, a benzofuranyl group, a benzothienyl group, an indolyl group, a carbazolyl group, a benzoxazolyl group, a benzothiazolyl group, a quinoxalyl group, a benzoimidazolyl group, a pyrazolyl group, a dibenzofuranyl group, and a dibenzothienyl group. In some embodiments, Ar₁ to Ar₄ may each independently be selected from the phenyl group, the biphenyl group, the terphenyl group, the fluorenyl group, the carbazolyl group, the dibenzofuranyl group, and the like.

Except for when L₁ is direct linkage (e.g., a chemical bond, such as a single bond), non-limiting examples of L₁ may include a phenylene group, a biphenylylene group, a terphenylylene group, a naphthylene group, an anthrylene group, a phenanthrylene group, a fluorendiyl group, an indanediyl group, a pyrenediyl group, an acenaphthenediyl group, a fluoranthenediyl group, a triphenylenediyl group, a pyridinediyl group, a furandiyl group, a pyrandiyl group, a thiophenediyl group, a quinolinediyl group, an isoquinolinediyl group, a benzofurandiyl group, a benzothiophenediyl group, an indolediyl group, a carbazolediyl group, a benzoxazolediyl group, a benzothiazolediyl group, a quinoxalyldiyl group, a benzoimidazolediyl group, a pyrazolediyl group, a dibenzofurandiyl group, and the like. In some embodiments, L₁ may be selected from the phenylene group, the terphenylene group, the fluorenediyl group, the carbazolediyl group, the dibenzofuranediyl group, and the like.

Non-limiting examples of the compound represented by Formula (2) may include one of the following Compounds 16 to 31. In the formulae for Compounds 16 to 31, the symbol “Me” refers to a methyl group. However, the compound represented by Formula (2) is not limited thereto.

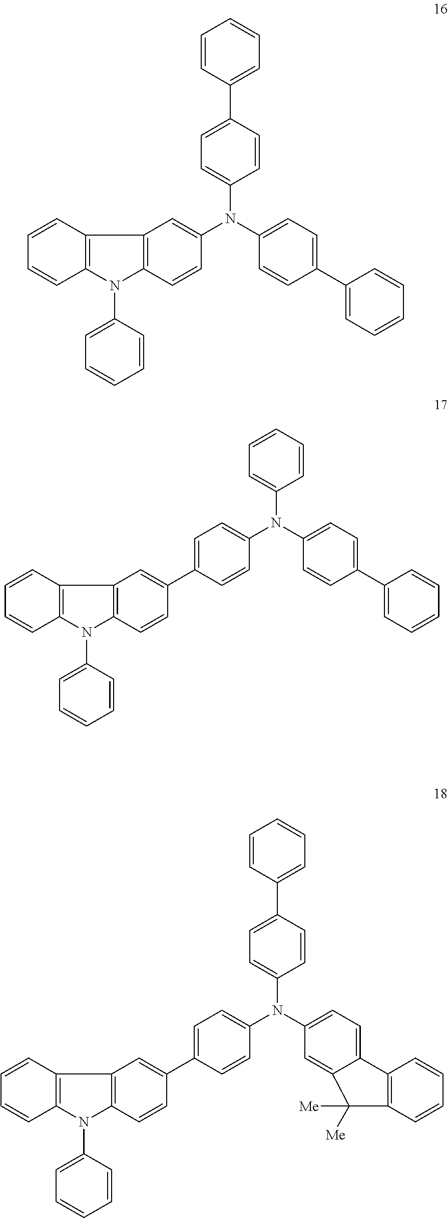 [SMILES: c1ccc(-c2ccc(N(c3ccc(-c4ccccc4)cc3)c3ccc4c(c3)c3ccccc3n4-c3ccccc3)cc2)cc1 ; c1ccc(-c2ccc(N(c3ccccc3)c3ccc(-c4ccc5c(c4)c4ccccc4n5-c4ccccc4)cc3)cc2)cc1 ; CC1(C)c2ccccc2-c2ccc(N(c3ccc(-c4ccccc4)cc3)c3ccc(-c4ccc5c(c4)c4ccccc4n5-c4ccccc4)cc3)cc21]

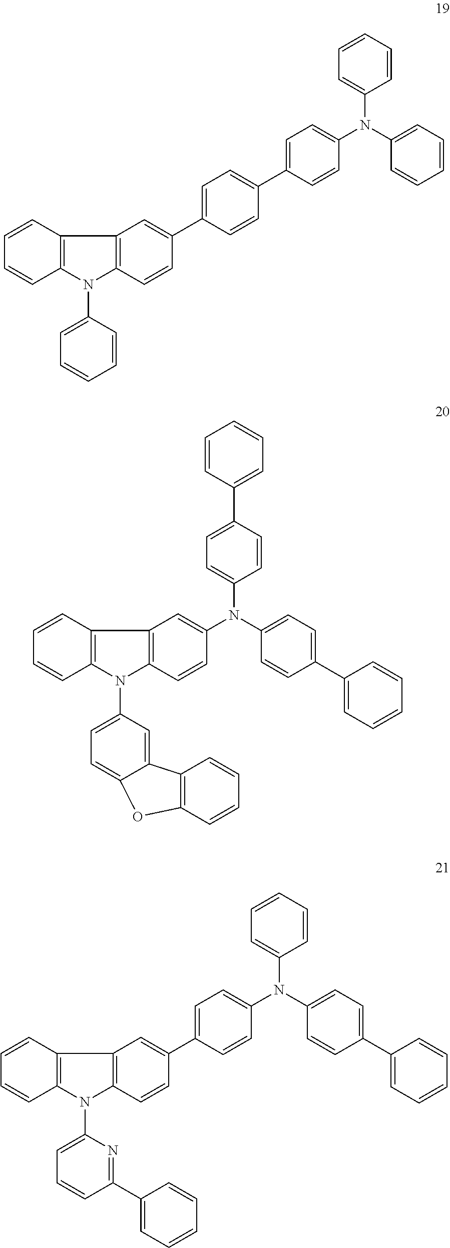 [SMILES: c1ccc(N(c2ccccc2)c2ccc(-c3ccc(-c4ccc5c(c4)c4ccccc4n5-c4ccccc4)cc3)cc2)cc1 ; c1ccc(-c2ccc(N(c3ccc(-c4ccccc4)cc3)c3ccc4c(c3)c3ccccc3n4-c3ccc4oc5ccccc5c4c3)cc2)cc1 ; c1ccc(-c2ccc(N(c3ccccc3)c3ccc(-c4ccc5c(c4)c4ccccc4n5-c4cccc(-c5ccccc5)n4)cc3)cc2)cc1]

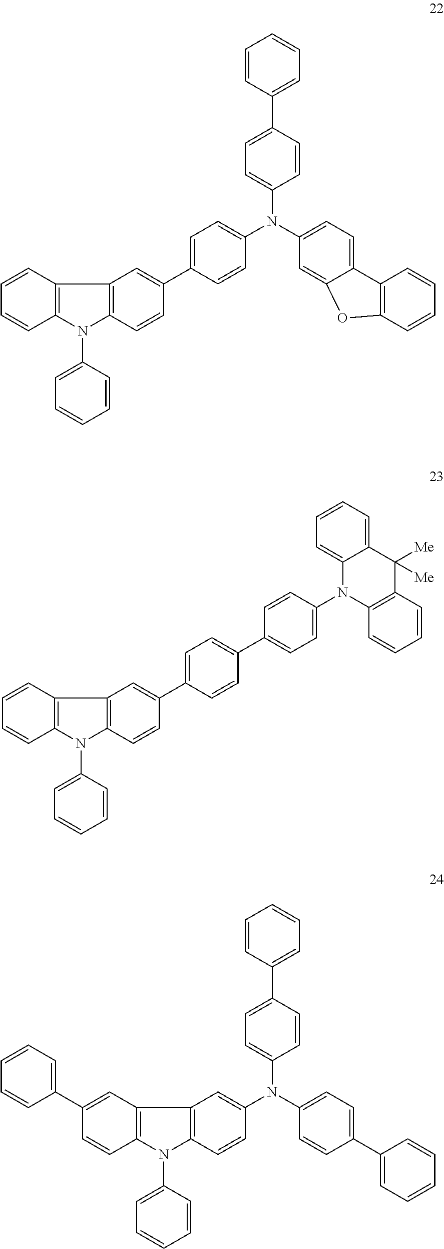 [SMILES: c1ccc(-c2ccc(N(c3ccc(-c4ccc5c(c4)c4ccccc4n5-c4ccccc4)cc3)c3ccc4c(c3)oc3ccccc34)cc2)cc1 ; CC1(C)c2ccccc2N(c2ccc(-c3ccc(-c4ccc5c(c4)c4ccccc4n5-c4ccccc4)cc3)cc2)c2ccccc21 ; c1ccc(-c2ccc(N(c3ccc(-c4ccccc4)cc3)c3ccc4c(c3)c3cc(-c5ccccc5)ccc3n4-c3ccccc3)cc2)cc1]

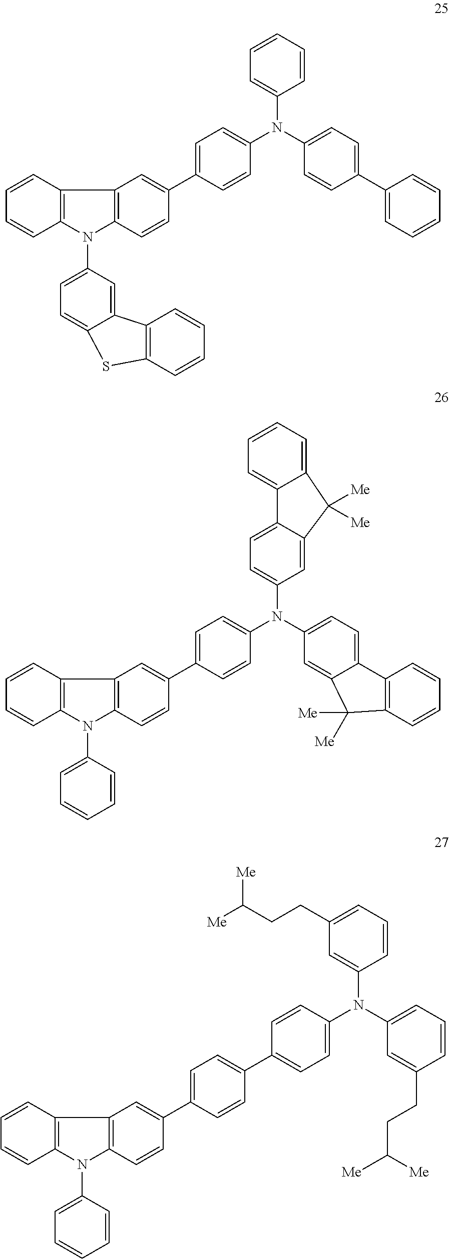 [SMILES: c1ccc(-c2ccc(N(c3ccccc3)c3ccc(-c4ccc5c(c4)c4ccccc4n5-c4ccc5sc6ccccc6c5c4)cc3)cc2)cc1 ; CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21 ; CC(C)CCc1cccc(N(c2ccc(-c3ccc(-c4ccc5c(c4)c4ccccc4n5-c4ccccc4)cc3)cc2)c2cccc(CCC(C)C)c2)c1]

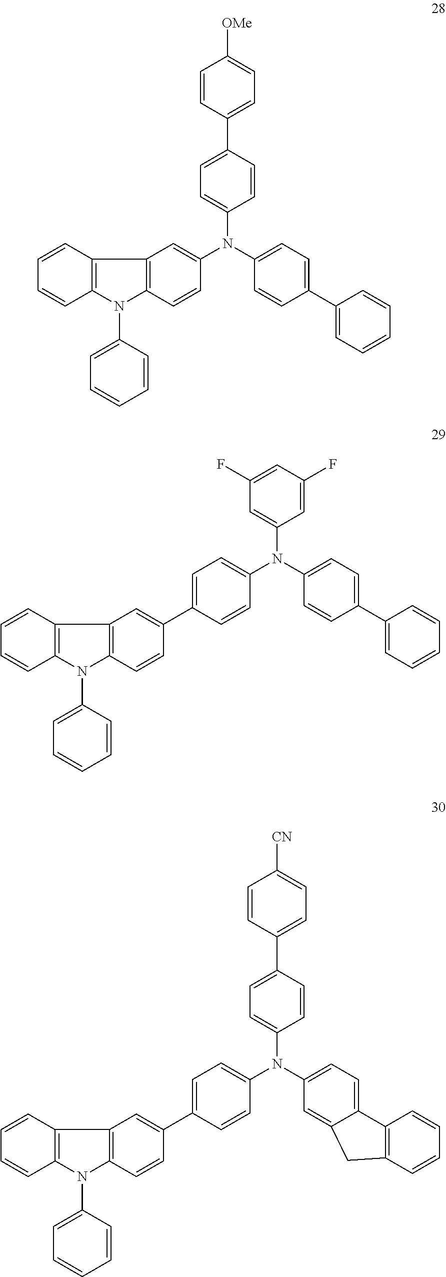 [SMILES: COc1ccc(-c2ccc(N(c3ccc(-c4ccccc4)cc3)c3ccc4c(c3)c3ccccc3n4-c3ccccc3)cc2)cc1 ; Fc1cc(F)cc(N(c2ccc(-c3ccccc3)cc2)c2ccc(-c3ccc4c(c3)c3ccccc3n4-c3ccccc3)cc2)c1 ; N#Cc1ccc(-c2ccc(N(c3ccc(-c4ccc5c(c4)c4ccccc4n5-c4ccccc4)cc3)c3ccc4c(c3)Cc3ccccc3-4)cc2)cc1]

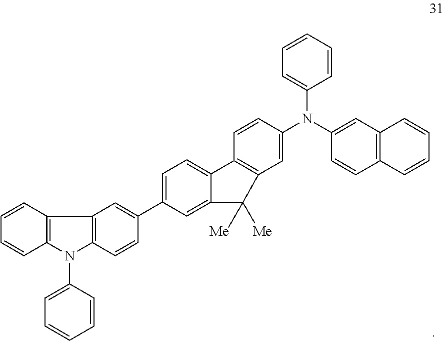 [SMILES: CC1(C)c2cc(-c3ccc4c(c3)c3ccccc3n4-c3ccccc3)ccc2-c2ccc(N(c3ccccc3)c3ccc4ccccc4c3)cc21]

In some embodiments, in the hole transport band 120 of the organic EL device 100, the laminate structure having at least three layers may further include at least one layer (e.g., a third layer 123, herein also referred to as “a hole transport layer”) between the anode 110 and the second layer 125 and including the compound represented by Formula (2). In the laminate structure, the position of the third layer 123 is not specifically limited. For example, the third layer 123 may be positioned between the first layer 121 and the second layer 125. The compound represented by Formula (2) and included in the third layer 123 may be selected from Compounds 16 to 31, which have a carbazolyl group and which may be also included in the first layer 121.

In the organic EL device 100, in the laminate structure positioned in the hole transport band 120 and having at least three layers having different components (e.g., having different compositions), at least one layer including the hole transport compound doped with an electron accepting compound having a LUMO level from about −9.0 eV to about −4.0 eV (e.g., the first layer 121) may be positioned adjacent to the anode 110, and at least one layer including the compound represented by Formula (1) (e.g., the second layer 125) may be positioned adjacent to the emission layer 130. In the organic EL device 100 according to embodiments of the present disclosure, when a compound including an amine derivative having a carbazolyl group (e.g., the compound represented by Formula (1)) is included in the second hole transport layer 125 positioned adjacent to the emission layer 130 in the laminate structure, the hole transport laminate structure may be passivated from the electrons not consumed in the emission layer 130. In addition, the diffusion of energy with an excited state (e.g., the diffusion of excitons) generated in the emission layer 130 into the hole transport laminate structure may be prevented or reduced, and the charge balance of the organic EL device 100 may be controlled.

In the organic EL device 100, the first layer 121 including the electron accepting compound may be positioned closer to the anode 110, for example, adjacent to the anode 110. By placing the acceptor layer adjacent to the anode 110, hole injection properties of the anode (e.g., hole injection from the anode) may be improved. For example, the acceptor layer may be included in the first layer 121. In some embodiments, when a hole transport compound having a carbazolyl group (e.g., the compound represented by Formula (2)) is further included in the first layer 121, charge transport properties and current flow durability may be improved.

In the organic EL device 100, the third layer 123 including the compound having a carbazolyl group (e.g., the compound represented by Formula (2)) may be positioned closer to the emission layer 130 than the first layer 121. By including the compound having a carbazolyl group in the hole transport laminate structure, charge transport properties and current flow durability may be improved. In some embodiments, by including the compound represented by Formula (2) in the third layer 123, the hole transport laminate structure may be passivated from electrons not consumed in the emission layer 130, and the diffusion of energy of an excited state (e.g., the diffusion of excitons) generated in the emission layer 130 into the hole transport laminate structure may be prevented or reduced. In some embodiments, including an amine derivative having a carbazolyl group (e.g., the compound represented by Formula (2)) may restrain or reduce the diffusion of the electron accepting compound into the emission layer 130.

In some embodiments, by placing the second layer 125 including the compound represented by Formula (1) adjacent to the emission layer 130, the diffusion of the electron accepting compound included in the first layer 121 into the emission layer 130 may be restrained or reduced, the first layer 121 and the third layer 123 may be passivated from electrons not consumed in the emission layer 130, and, the diffusion of energy of an excited state (e.g., the diffusion of excitons) generated in the emission layer 130 into the first layer 121 and the third layer 123 may be prevented or reduced. In some embodiments, by including an amine derivative having a carbazolyl group (e.g., the compound represented by Formula (1)) in the second layer 125, the hole transport properties and the current flow durability of the laminate structure may be improved.

In the laminate structure positioned in the hole transport band 120 between the anode 110 and the emission layer 130 in the organic EL device 100, the compound having a carbazolyl group may be included in at least three layers of the laminate structure. By including the compound having a carbazolyl group in the hole transport laminate structure, charge transport properties and current flow durability may be improved. In some embodiments, in the laminate structure positioned in the hole transport band 120 between the anode 110 and the emission layer 130 in the organic EL device 100, at least one selected from the compound represented by Formula (1) and the compound represented by Formula (2) may be included in the at least three layers of the laminate structure. Thus, the hole transport laminate structure may be passivated from electrons not consumed in the emission layer 130, and the diffusion of energy of an excited state (e.g., the diffusion of excitons) generated in the emission layer 130 into the hole transport laminate structure may be prevented or reduced.

In the organic EL device 100, light emission via a singlet excited state may be obtained in the emission layer 130. As a material for forming the emission layer 130, any suitable luminescent material generally available in the art of display devices may be used, without specific limitation. For example, the material for forming the emission layer 130 may be selected from a fluoranthene derivative, a pyrene derivative, an arylacetylene derivative, a fluorene derivative, a perylene derivative, a chrysene derivative, and the like. In some embodiments, the pyrene derivative, the perylene derivative, and/or the anthracene derivative may be used. For example, an anthracene derivative represented by Formula (3) may be used as the material for forming the emission layer 130.

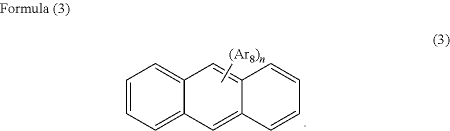

In Formula (3), each Ar₈ may independently be selected from a hydrogen atom, a deuterium atom, a substituted or unsubstituted aryl group having 6 to 30 carbon atoms for forming a ring, a substituted or unsubstituted heteroaryl group having 3 to 30 carbon atoms for forming a ring, and an alkyl group having 1 to 10 carbon atoms; and n may be an integer from 1 to 10.

Non-limiting examples of Ar₈ may include a phenyl group, a biphenyl group, a terphenyl group, a naphthyl group, a phenylnaphthyl group, a naphthylphenyl group, an anthryl group, a phenanthryl group, a fluorenyl group, an indenyl group, a pyrenyl group, an acetonaphthenyl group, a fluoranthenyl group, a triphenylenyl group, a pyridyl group, a furanyl group, a pyranyl group, a thienyl group, a quinolyl group, an isoquinolyl group, a benzofuranyl group, a benzothienyl group, an indolyl group, a carbazolyl group, a benzoxazolyl group, a benzothiazolyl group, a quinoxalyl group, a benzoimidazolyl group, a pyrazolyl group, a dibenzofuranyl group, and a dibenzothienyl group. In some embodiments, Ar₈ may be selected from the phenyl group, the biphenyl group, the terphenyl group, the fluorenyl group, the carbazolyl group, the dibenzofuranyl group, and the like.

The compound represented by Formula (3) may be represented by one of Compounds a-1 to a-12. In the formulae for Compounds a-1 to a-12, the symbol “D” refers to deuterium. However, the compound represented by Formula (3) is not limited thereto.

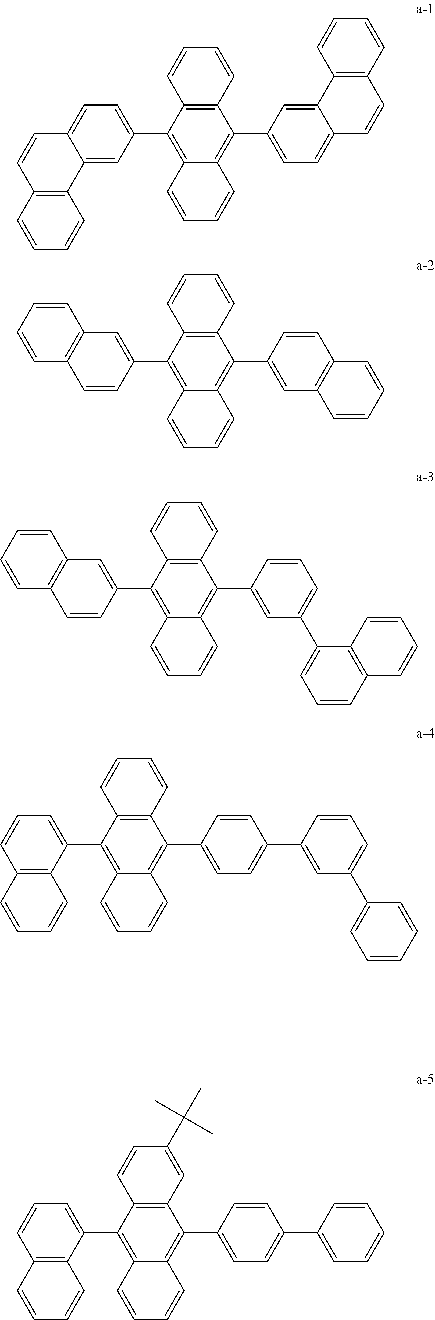

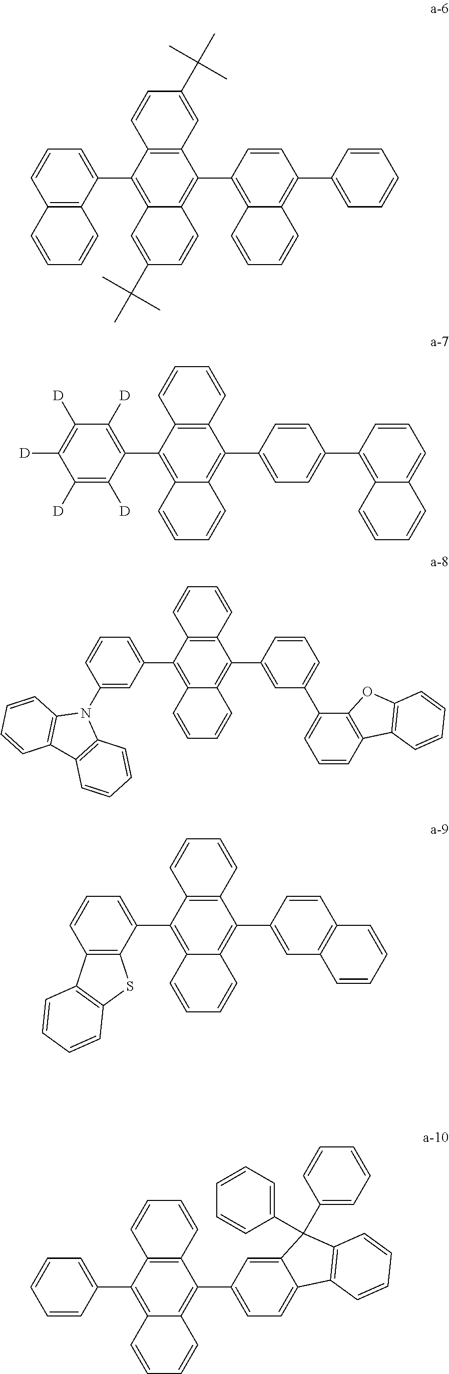

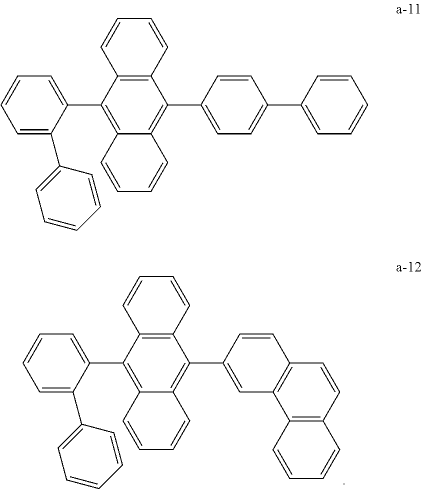

As described above, the organic EL device 100 of embodiments of the present disclosure may facilitate improved hole injection properties of the anode 110 (e.g., hole injection from the anode 110) by including at least one layer (e.g., the first layer 121) including the hole transport compound doped with the electron accepting compound having a LUMO level from about −9.0 eV to about −4.0 eV. When the emission layer 130 of the organic EL device 100 further includes the compound represented by Formula (3), low driving voltage of the organic EL device 100 may be realized.

The organic EL device according to embodiments of the present disclosure will be explained in more detail by referring to the organic EL device 100 shown in FIG. 1. In the organic EL device 100 according to one or more embodiments of the present disclosure, the substrate 101 may be, for example, a transparent glass substrate, a semiconductor substrate formed by using silicon, and/or the like, or a flexible substrate of a resin and/or the like. The anode 110 may be positioned on the substrate 101, and may be formed using indium tin oxide (ITO), indium zinc oxide (IZO), and/or the like.

As described above, the hole transport band 120 may be positioned between the anode 110 and the emission layer 130. In some embodiments, a hole injection layer is formed as the first layer 121 by doping the electron accepting compound into the hole transport compound on the anode 110. As the hole transport compound, the compound represented by Formula (2) may be used.

The hole transport layer may be formed as the third layer 123 using a hole transport material (e.g., the compound represented by Formula (2)), and the third layer 123 may be adjacent to the hole injection layer (e.g., the first layer 121), such that the third layer 123 is closer to the emission layer 130 than the first layer 121. In some embodiments, the hole transport layer (e.g., the third layer 123) may be laminated in plural (e.g., the third layer 123 may have a multilayer structure), and in this case, the layer of the multilayer-structured third layer 123 that is positioned closest to the hole injection layer (e.g., the first layer 121) may include the electron accepting compound.

An intermediate layer may be formed as the second layer 125 using a hole transport material (e.g., the compound represented by Formula (1)) and may be adjacent to the hole transport layer (e.g., the third layer 123), such that the second layer 125 is closer to the emission layer 130 than the third layer 123. In some embodiments, the intermediate layer (e.g., the second layer 125) is adjacent to the emission layer 130. Thus, the diffusion of the electron accepting compound included in the hole injection layer (e.g., the first layer 121) and/or the hole transport layer (e.g., the third layer 123) into the emission layer 130 may be restrained or reduced, the hole transport laminate structure may be passivated from electrons not consumed in the emission layer 130, and the diffusion of energy of an excited state (e.g., the diffusion of excitons) generated in the emission layer 130 into the hole transport laminate structure may be prevented or reduced. Accordingly, the emission efficiency and the life of the organic EL device may be improved.

The emission layer 130 may be formed adjacent to the intermediate layer (e.g., the third layer 125). As the host material of the emission layer 130, for example, an anthracene derivative represented by Formula (3) may be used. The emission layer 130 may further include any suitable p-type dopant such as, for example, 2,5,8,11-tetra-t-butylperylene (TBP), but embodiments of the present disclosure are not limited thereto.

The electron transport layer 140 may be formed on the emission layer 130 using, for example, a material including tris(8-hydroxyquinolinato)aluminum (Alq3). On the electron transport layer 140, the electron injection layer 150 may be formed using a material including, for example, lithium fluoride, lithium 8-quinolinato, and/or the like. On the electron injection layer 150, the cathode 160 may be formed using a metal such as Al, Ag, and/or the like and/or a transparent material such as ITO, IZO, and/or the like. Each of the above-described layers may be formed by selecting an appropriate layer forming method according to the material included in each layer, for example, a vacuum deposition method, a sputtering method, various coating methods, and/or the like.

The organic EL device according to embodiments of the present disclosure may be connected (e.g.. coupled) to a thin film transistor (TFT) of an active-matrix organic EL display.

In the organic EL device 100 having the above-described layer structure and materials according to embodiments of the present disclosure, the hole transport laminate structure may be passivated from electrons not consumed in the emission layer 130, the diffusion of energy of an excited state (e.g., the diffusion of excitons) generated in the emission layer 130 into the hole transport laminate structure may be prevented or reduced, and the charge balance of the organic EL device 100 may be controlled. In some embodiments, by placing the intermediate layer (e.g., the second layer 125) near the emission layer 130, the diffusion of the electron accepting compound from the first layer 121 and/or third layer 123 into the emission layer 130 may be restrained or reduced, and the emission efficiency and the life of the organic EL device may be improved.

### 1-2. EXAMPLES

### Preparation Method

Organic EL devices according to embodiments of the present disclosure were manufactured using the above-described materials. FIG. 2 is a schematic diagram illustrating an organic EL device 200 according to one or more embodiments of the present disclosure. In FIG. 2, an anode 110 was formed using ITO to a layer thickness of about 150 nm. A hole injection layer 221 was formed to a layer thickness of about 10 nm using HTL1 material including either Compound 18 or Compound 34 as the compound represented by Formula (2), and doped with Compound 32 represented by Formula ac14 as the electron accepting compound. A hole transport layer 223 was formed to a layer thickness of about 10 nm using HTL2 material including either Compound 18 or Compound 35. An intermediate layer 225 was formed to a layer thickness of about 10 nm using HTL3 material including Compound 4 as the compound represented by Formula (1).

Then, an emission layer 130 was formed to a layer thickness of about 25 nm using a host material including 9,10-di(2-naphthyl)anthracene (ADN) as the compound represented by Formula (3), doped with about 3% of TBP. An electron transport layer 140 was formed using Alq3 to a layer thickness of about 25 nm, an electron injection layer 150 was formed using LiF to a layer thickness of about 1 nm, and a cathode 160 was formed using Al to a layer thickness of about 100 nm.

The organic EL devices of Examples 1-1 to 1-3 and Comparative Examples 1-1 to 1-4 were each independently manufactured in substantially the same manner as described above, except the HTL1, HTL2, and HTL3 materials in each Example and Comparative Example included the compounds as shown in Table 1.

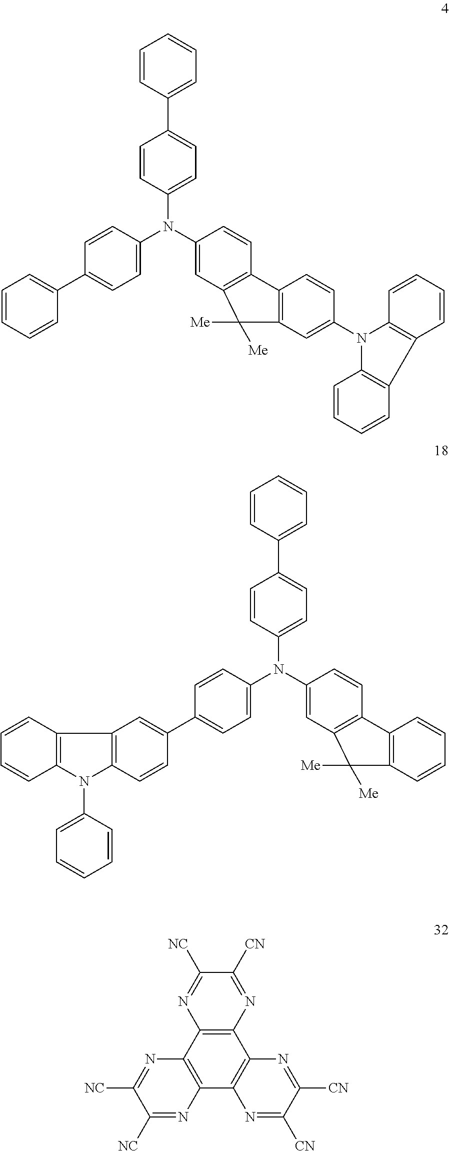 [SMILES: CC1(C)c2cc(N(c3ccc(-c4ccccc4)cc3)c3ccc(-c4ccccc4)cc3)ccc2-c2ccc(-n3c4ccccc4c4ccccc43)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21 ; N#Cc1nc2c3nc(C#N)c(C#N)nc3c3nc(C#N)c(C#N)nc3c2nc1C#N]

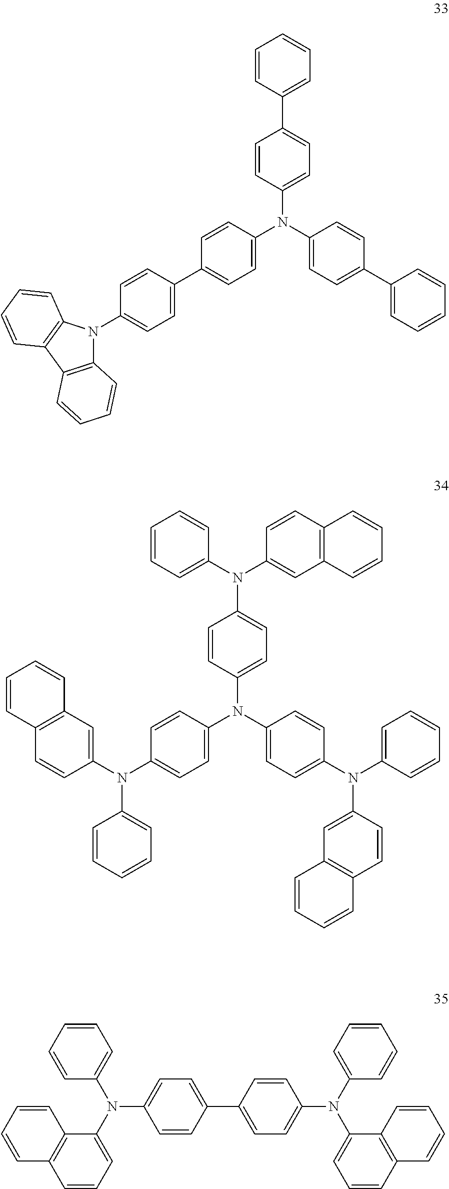 [SMILES: c1ccc(-c2ccc(N(c3ccc(-c4ccccc4)cc3)c3ccc(-c4ccc(-n5c6ccccc6c6ccccc65)cc4)cc3)cc2)cc1 ; c1ccc(N(c2ccc(N(c3ccc(N(c4ccccc4)c4ccc5ccccc5c4)cc3)c3ccc(N(c4ccccc4)c4ccc5ccccc5c4)cc3)cc2)c2ccc3ccccc3c2)cc1 ; c1ccc(N(c2ccc(-c3ccc(N(c4ccccc4)c4cccc5ccccc45)cc3)cc2)c2cccc3ccccc23)cc1]

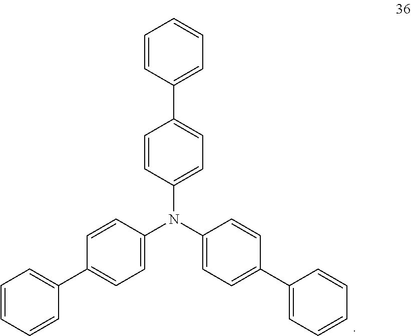 [SMILES: c1ccc(-c2ccc(N(c3ccc(-c4ccccc4)cc3)c3ccc(-c4ccccc4)cc3)cc2)cc1]

TABLE 1

| | HTL1 | HTL2 | HTL3 |
|---|---|---|---|
| Example 1-1 | Compounds | Compound 18 | Compound 4 |
| | 18 + 32 | | |
| Example 1-2 | Compounds | Compound 18 | Compound 4 |
| | 34 + 32 | | |
| Example 1-3 | Compounds | Compound 35 | Compound 4 |
| | 18 + 32 | | |
| Comparative | Compounds | Compound 4 | Compound 18 |
| Example 1-1 | 18 + 32 | | |
| Comparative | Compounds 18 | Compound 18 | Compound 4 |
| Example 1-2 | | | |
| Comparative | Compound | Compounds 18 | Compound 33 |
| Example 1-3 | 18 + 32 | | |
| Comparative | Compounds | Compound 18 | Compound 36 |
| Example 1-4 | 18 + 32 | | |

Voltage, power efficiency, and current efficiency of the organic EL devices manufactured in the Examples and Comparative Examples were evaluated. Current density was about 10 mA/cm². Evaluation results are shown in Table 2.

TABLE 2

| | | Emission | |
|---|---|---|---|
| | Voltage (V) | efficiency (cd/A) | Half life (h) |
| Example 1-1 | 6.3 | 7.7 | 3,700 |
| Example 1-2 | 6.4 | 7.6 | 3,200 |
| Example 1-3 | 6.3 | 7.5 | 2,700 |
| Comparative | 6.5 | 7.2 | 2,300 |
| Example 1-1 | | | |
| Comparative | 7.6 | 6.8 | 2,000 |
| Example 1-2 | | | |
| Comparative | 6.6 | 7.3 | 2,600 |
| Example 1-3 | | | |
| Comparative | 6.4 | 7.3 | 2,300 |
| Example 1-4 | | | |

As shown in Table 2, the driving voltage of the organic EL devices of Examples 1-1 to 1-3 according to embodiments of the present disclosure was lower and the emission efficiency and half life was improved as compared to the organic EL device of Comparative Example 1-2, in which the HTL1 material included in the hole injection layer was not doped with the electron accepting Compound 32. In addition, the driving voltage was slightly lowered and the emission efficiency and half life of the device was improved in the organic EL device of Example 1-2, in which the electron accepting compound was doped into the non-carbazole-based hole transport material (Compound 34). In addition, the driving voltage was lowered and the emission efficiency and half life of the device was improved in the organic EL device of Example 1-3, in which the non-carbazole-based hole transport compound (Compound 35) was used in the HTL2 material included in the hole transport layer. Also, the organic EL device of Example 1-1 exhibited lower driving voltage and improved emission efficiency and half life when compared with the organic EL device of Comparative Example 1-1, in which the compounds respectively used as the HTL2 and HTL3 materials in Example 1-1 were reversed (as shown in Table 2). In addition, each of the organic EL devices of Examples 1-1 to 1-3 exhibited lower driving voltage and improved emission efficiency and half life when compared with the organic EL device of Comparative Example 1-2, in which the electron accepting compound was not included in the HTL1 material. Each of the organic EL devices of Examples 1-1 to 1-3 also exhibited slightly lower driving voltage and improved emission efficiency and half life when compared with the organic EL device of Comparative Example 1-3, in which the compound represented by Formula (1) and included in the HTL3 material of the intermediate layer was Compound 33 (in which L₂ in Formula (1) is a biphenyl group), instead of Compound 4 (in which L₂ in Formula (1) is a fluorenediyl group). In addition, the improvement of the emission efficiency and half life was observed in the organic EL devices of Examples 1-1 to 1-3, as compared with the organic EL device of Comparative Example 1-4, in which a non-carbazole-based hole transport material was used as the HTL3 material, instead of the carbazole-based compound of Formula (1).

As described above, in the laminate structure including at least three layers having different components (e.g., having different compositions), the laminate structure being positioned in the hole transport band in the organic EL device of embodiments of the present disclosure, at least one layer including the hole transport compound doped with the electron accepting compound having a LUMO level from about −9.0 eV to about −4.0 eV may be adjacent to the anode and at least one layer including the compound represented by Formula (1) may be between the layer including the hole transport compound doped with the electron accepting compound and the emission layer and adjacent to the emission layer, thus providing an organic EL device having high efficiency and long life.

2-1. Organic EL Device Including a First Layer Formed using Electron Accepting—Compound as Main Material

Hereinafter, a possible modification of the organic EL device 100, in which the first layer is formed by mainly using an electron accepting compound, will be explained referring to FIG. 1.

In the organic EL device 100 of the present embodiments, a laminate structure (herein, also referred to as “a hole transport laminate structure”) including at least three layers having different components (e.g., having different compositions) may be positioned between an anode 110 and an emission layer 130 from which light may be emitted via a singlet excited state. The laminate structure may include a first layer 121 formed by mainly using an electron accepting compound having a LUMO level from about −9.0 eV to about −4.0 eV, and a second layer 125 between the first layer and the emission layer, the second layer 125 being adjacent to the emission layer and including a compound represented by Formula (1).

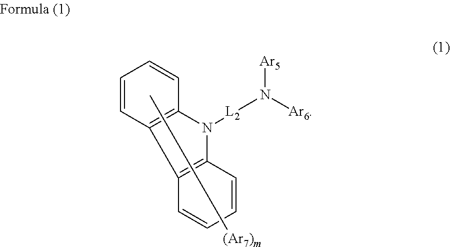

In Formula (1), Ar₅, Ar₆ and Ar₇ may each independently be selected from a substituted or unsubstituted aryl group having 6 to 30 carbon atoms for forming a ring, a substituted or unsubstituted heteroaryl group having 3 to 30 carbon atoms for forming a ring, an alkyl group having 1 to 10 carbon atoms, and an alkenyl group having 1 to 10 carbon atoms; L₂ may be a substituted or unsubstituted fluorenediyl group; and m may be an integer from 0 to 8.

The organic EL device of the present embodiments may have substantially the same structure as the above-described organic EL device, except that the first layer of the present embodiments may be formed by mainly using the electron accepting compound. In the present embodiments, the emission layer from which light may be emitted via a singlet excited state, and the second layer positioned between the first layer and the emission layer, the second layer being adjacent to the emission layer and including a compound represented by Formula (1), may be the same (or substantially the same) as described above, and duplicative descriptions thereof will not be provided. Hereinafter, the configuration of the first layer, insofar as it is different from the configuration of the first layer described above, will be explained in more detail.

In the organic EL device 100 according to embodiments of the present disclosure, improved hole injection properties of an anode (e.g., hole injection from an anode) may be facilitated, the hole transport laminate structure may be passivated from electrons not consumed in the emission layer, the diffusion of energy with an excited state (e.g., the diffusion of excitons) generated in the emission layer into the hole transport laminate structure may be prevented or reduced, and the total charge balance of the device may be controlled. Thus, the resulting organic EL device may exhibit lower driving voltage and improvement of emission efficiency and life.

In the laminate structure including at least three layers having different components (e.g., having different compositions) positioned in the hole transport band 120 in the organic EL device 100, at least one layer (e.g., the first layer 121) formed by mainly using an electron accepting compound having a LUMO level from about −9.0 eV to about −4.0 eV may be positioned near the anode 110, and at least one layer (e.g., the second layer 125) including the compound represented by Formula (1) may be positioned adjacent to the emission layer 130.

When the first layer is formed by mainly using the electron accepting compound having a LUMO level from about −9.0 eV to about −4.0 eV, hole injection properties of the anode 110 (e.g., hole injection from the anode 110) may be improved. In some embodiments, the first layer 121 including the electron accepting compound may be positioned near the anode 110, and in some embodiments, may be adjacent to the anode 110, and thus hole injection properties of the anode 110 (e.g., hole injection from the anode 110) of the organic EL device 100 may be improved.

The electron accepting compound may be included in the first layer 121 in an amount of about 50% or more by weight, based on the total weight of the materials constituting the first layer 121. The electron accepting compound of the present embodiments may be substantially similar to the electron accepting compound described above.

In some embodiments, in the hole transport band 120 of the organic EL device 100, the laminate structure including at least three layers may further include at least one layer (e.g., a third layer 123) including a compound represented by Formula (2) between the first layer 121 and the second layer 125. Description of Formula (2) is the same as the one provided above.

In some embodiments, in the organic EL device 100, light emission from the emission layer 130 may be obtained via a singlet excited state. As the material for forming the emission layer 130, any suitable luminescent material generally available in the art of display devices may be used, and non-limiting examples thereof include a fluoranthene derivative, a pyrene derivative, an arylacetylene derivative, a fluorene derivative, a perylene derivative, a chrysene derivative, and the like. In some embodiments, the pyrene derivative, the perylene derivative, and/or the anthracene derivative may be used as the material for forming the emission layer 130. For example, as the material for forming the emission layer 130, an anthracene derivative represented by Formula (3) may be used. Description of Formula (3) is the same as the one provided above.

In some embodiments, hole injection property of the anode 110 (e.g., hole injection from the anode 110) may be improved by forming the first layer 121 by mainly using the electron accepting compound having a LUMO level from about −9.0 eV to about −4.0 eV in the organic EL device 100 of the present embodiments. The above-mentioned effects may be further improved when the emission layer 130 includes the compound represented by Formula (3), for example, the low driving voltage of the organic EL device 100 may be realized.

### 2-2. EXAMPLES

### Preparation Method

An organic EL device according to the present embodiments was manufactured using the above-mentioned materials. FIG. 2 is a schematic diagram illustrating an organic EL device 200 according to embodiments of the present disclosure. In the organic EL device 200, an anode 110 was formed using ITO to a layer thickness of about 150 nm. A hole injection layer 221 was formed to a layer thickness of about 10 nm using HTL1 material including Compound 32 represented by structure ac14 as an electron accepting compound. A hole transport layer 223 was formed to a layer thickness of about 10 nm using HTL2 material including the compound represented by Formula (2) (e.g., Compound 18 and/or Compound 34). An intermediate layer 225 was formed to a layer thickness of about 10 nm using HTL3 material including the compound represented by Formula (1) (e.g., Compound 4).

Then, an emission layer 130 was formed using a host material including ADN as the compound represented by Formula (3), doped with about 3% of TBP to a layer thickness of about 25 nm. An electron transport layer 140 was formed using Alq3 to a layer thickness of about 25 nm, an electron injection layer 150 was formed using LiF to a layer thickness of about 1 nm, and a cathode 160 was formed using Al to a layer thickness of about 100 nm.

The organic EL devices of Examples 2-1 to 2-3 and Comparative Examples 2-1 to 2-4 were each independently manufactured in substantially the same manner as described above, except the HTL1, HTL2, and HTL3 materials in each Example and Comparative Example included the compounds as shown in Table 3.

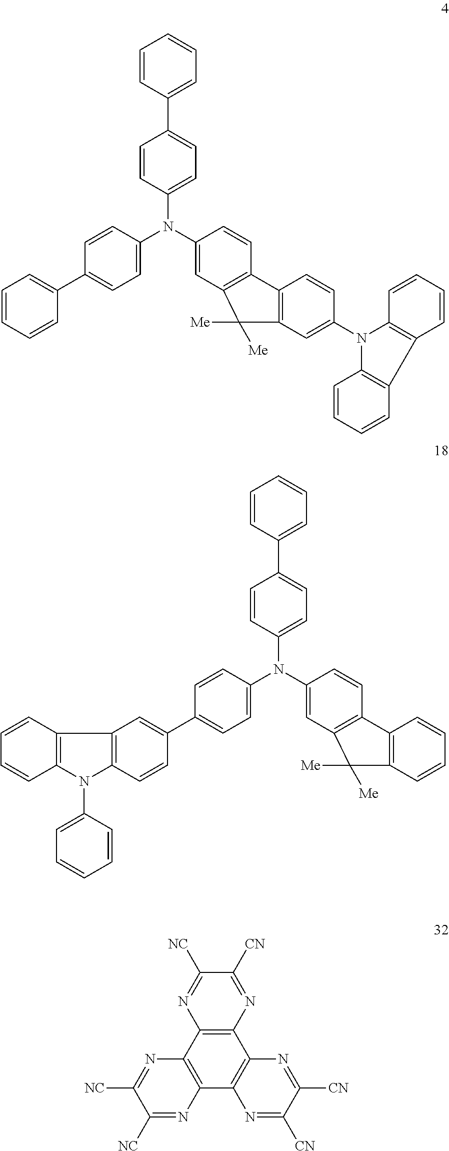 [SMILES: CC1(C)c2cc(N(c3ccc(-c4ccccc4)cc3)c3ccc(-c4ccccc4)cc3)ccc2-c2ccc(-n3c4ccccc4c4ccccc43)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21 ; N#Cc1nc2c3nc(C#N)c(C#N)nc3c3nc(C#N)c(C#N)nc3c2nc1C#N]

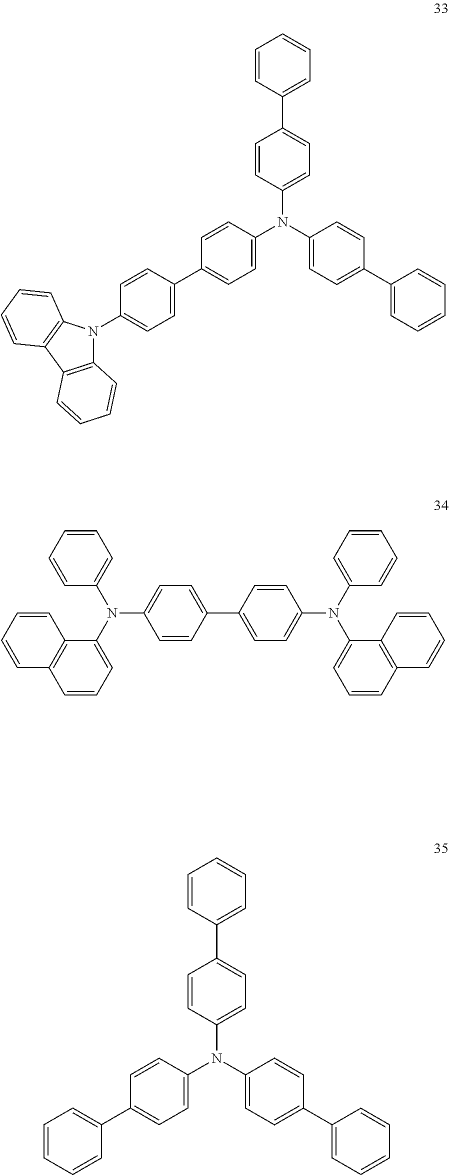 [SMILES: c1ccc(-c2ccc(N(c3ccc(-c4ccccc4)cc3)c3ccc(-c4ccc(-n5c6ccccc6c6ccccc65)cc4)cc3)cc2)cc1 ; c1ccc(N(c2ccc(-c3ccc(N(c4ccccc4)c4cccc5ccccc45)cc3)cc2)c2cccc3ccccc23)cc1 ; c1ccc(-c2ccc(N(c3ccc(-c4ccccc4)cc3)c3ccc(-c4ccccc4)cc3)cc2)cc1]

TABLE 3

| | HTL1 | HTL2 | HTL3 |
|---|---|---|---|
| Example 2-1 | Compounds 32 | Compound 18 | Compound 4 |
| Example 2-2 | Compounds 32 | Compound 34 | Compound 4 |
| Comparative | Compounds 32 | Compound 4 | Compound 18 |
| Example 2-1 | | | |
| Comparative | Compounds 18 | Compound 18 | Compound 4 |
| Example 2-2 | | | |
| Comparative | Compound 32 | Compounds 18 | Compound 33 |
| Example 2-3 | | | |
| Comparative | Compounds 32 | Compound 18 | Compound 35 |
| Example 2-4 | | | |

Voltage, power efficiency, and current efficiency of the organic EL devices manufactured in the Examples and Comparative Examples were evaluated. Current density was about 10 mA/cm². Evaluation results are shown in Table 4.

TABLE 4

| | | Emission | |
|---|---|---|---|
| | Voltage (V) | efficiency (cd/A) | Half life (h) |
| Example 2-1 | 6.5 | 7.7 | 3,500 |
| Example 2-2 | 6.5 | 7.5 | 2,700 |
| Comparative | 6.8 | 7.2 | 2,000 |
| Example 2-1 | | | |
| Comparative | 7.6 | 6.8 | 2,000 |
| Example 2-2 | | | |
| Comparative | 6.7 | 7.4 | 2,500 |
| Example 2-3 | | | |
| Comparative | 6.5 | 7.3 | 2,400 |
| Example 2-4 | | | |

As shown in Table 4, the organic EL devices of Examples 2-1 and 2-2 exhibited decreased driving voltage, improved emission efficiency, and increased half life as compared with the organic EL device of Comparative Example 2-1, in which the compounds respectively used as the HTL2 and HTL3 materials in Example 2-1 were reversed (as shown in Table 2), and the organic EL device of Comparative Example 2-2, in which the electron accepting compound was not included in the HTL1 material. In addition, the organic EL device of Example 2-2, in which a non-carbazole-based hole transport material (Compound 34) was used as the HTL2 material included the hole transport layer, exhibited decreased driving voltage, improved emission efficiency, and increased half life. Also, the organic EL device of Example 2-1 exhibited decreased driving voltage, improved emission efficiency, and increased half life as compared with the organic EL device of Comparative Example 2-3, in which the compound represented by Formula (1) and included in the HTL3 material of the intermediate layer was Compound 33 (in which L₂ in Formula (1) is a biphenyl group), instead of Compound 4 (in which L₂ in Formula (1) is a fluorenediyl group), and as compared with the organic EL device of Comparative Example 2-4, in which a non-carbazole-based hole transport Compound 35 was used as the HTL3 material.

According to one or more embodiments of the present disclosure, an organic EL device having high efficiency of the driving voltage and long life may be provided by positioning a laminate structure including at least three layers having different components (e.g., having different compositions) in a hole transport band of the organic EL device between an anode and an emission layer, where at least one layer of the laminate structure is formed by mainly using the electron accepting compound having a LUMO level from about −9.0 eV to about −4.0 eV and is positioned near the anode, and at least one layer of the laminate structure includes the compound represented by Formula (1) and is positioned between the layer formed by mainly using the electron accepting compound and the emission layer, the layer including the compound represented by Formula (1) being adjacent to the emission layer.

As used herein, expressions such as “at least one of,” “one of,” “at least one selected from,” and “selected from,” when preceding a list of elements, modify the entire list of elements and do not modify the individual elements of the list. Further, the use of “may” when describing embodiments of the present disclosure refers to “one or more embodiments of the present disclosure.”

In addition, as used herein, the terms “use,” “using,” and “used” may be considered synonymous with the terms “utilize,” “utilizing,” and “utilized,” respectively.

As used herein, the term “substantially,” “about,” and similar terms are used as terms of approximation and not as terms of degree, and are intended to account for the inherent deviations in measured or calculated values that would be recognized by those of ordinary skill in the art.

Also, any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. §1 12, first paragraph, and 35 U.S.C. §132(a).

The above-disclosed embodiments are to be considered in the illustrative sense, and not as restrictive, and the appended claims and equivalents thereof are intended to cover all such modifications, enhancements, and other embodiments, which fall within the spirit and scope of the present disclosure. Thus, to the maximum extent allowed by law, the scope of the present disclosure is to be determined by the broadest permissible interpretation of the following claims and their equivalents, and shall not be restricted or limited by the foregoing detailed description.

What is claimed is:

1. An organic electroluminescent (EL) device comprising:
an anode,
a cathode,
an emission layer between the anode and the cathode, and
a laminate structure between the anode and the emission layer, the laminate structure comprising at least three layers, the at least three layers comprising:
a first layer comprising a hole transport compound doped with an electron accepting compound having a lowest unoccupied molecular orbital (LUMO) level from about −9.0 eV to about −4.0 eV; and
a second layer between the first layer and the emission layer, the second layer being adjacent to the emission layer and comprising a compound represented by Formula (1): 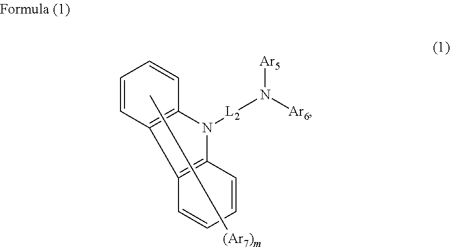
wherein, in Formula (1),
Ar₅, Ar₆ and Ar₇ are each independently selected from a substituted or unsubstituted aryl group having 6 to 30 carbon atoms for forming a ring, a substituted or unsubstituted heteroaryl group having 3 to 30 carbon atoms for forming a ring, an alkyl group having 1 to 10 carbon atoms, and an alkenyl group having 1 to 10 carbon atoms,
L₂ is a substituted or unsubstituted fluorenediyl group, and
m is an integer from 0 to 8.

2. The organic EL device of claim 1, wherein the at least three layers further comprise a third layer between the anode and the second layer, the third layer comprising a compound represented by Formula (2): 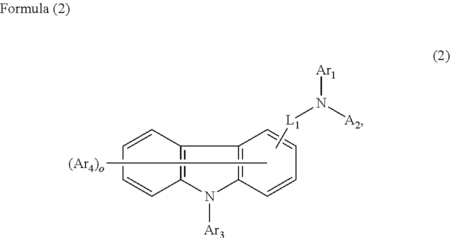
wherein, in Formula (2),
Ar₁, Ar₂ and Ar₃ are each independently selected from a substituted or unsubstituted aryl group having 6 to 30 carbon atoms for forming a ring, a substituted or unsubstituted heteroaryl group having 3 to 30 carbon atoms for forming a ring, an alkyl group having 1 to 10 carbon atoms, and an alkenyl group having 1 to 10 carbon atoms,
Ar₄ is selected from a substituted or unsubstituted aryl group having 6 to 30 carbon atoms for forming a ring, a substituted or unsubstituted heteroaryl group having 3 to 30 carbon atoms for forming a ring, an alkyl group having 1 to 10 carbon atoms, an alkenyl group having 1 to 10 carbon atoms, a deuterium atom, and a halogen atom,
L₁ is selected from a direct linkage, a substituted or unsubstituted arylene group having 6 to 30 carbon atoms for forming a ring, a heteroarylene group having 3 to 30 carbon atoms for forming a ring, and an alkylene group having 1 to 10 carbon atoms, and
o is an integer from 0 to 7.

3. The organic EL device of claim 1, wherein the hole transport compound in the first layer is represented by Formula (2): 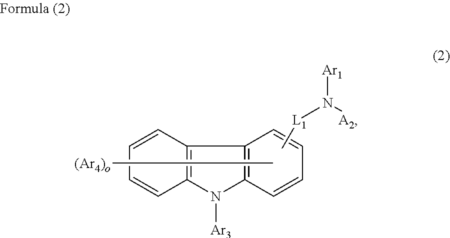
wherein, in Formula (2),
Ar₁ Ar₂ and Ar₃ are each independently selected from a substituted or unsubstituted aryl group having 6 to 30 carbon atoms for forming a ring, a substituted or unsubstituted heteroaryl group having 3 to 30 carbon atoms for forming a ring, an alkyl group having 1 to 10 carbon atoms, and an alkenyl group having 1 to 10 carbon atoms,
Ar₄ is selected from a substituted or unsubstituted aryl group having 6 to 30 carbon atoms for forming a ring, a substituted or unsubstituted heteroaryl group having 3 to 30 carbon atoms for forming a ring, an alkyl group having 1 to 10 carbon atoms, an alkenyl group having 1 to 10 carbon atoms, a deuterium atom, and a halogen atom,
L₁ is selected from a direct linkage, a substituted or unsubstituted arylene group having 6 to 30 carbon atoms for forming a ring, a heteroarylene group having 3 to 30 carbon atoms for forming a ring, and an alkylene group having 1 to 10 carbon atoms, and
o is an integer from 0 to 7.

4. The organic EL device of claim 1, wherein the emission layer comprises a compound represented by Formula (3): 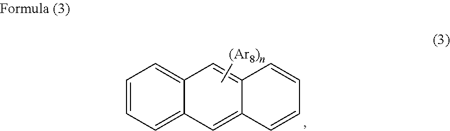
wherein, in Formula (3),
each Ar₈ is independently selected from a hydrogen atom, a deuterium atom, a substituted or unsubstituted aryl group having 6 to 30 carbon atoms for forming a ring, a substituted or unsubstituted heteroaryl group having 3 to 30 carbon atoms for forming a ring, and an alkyl group having 1 to 10 carbon atoms, and
n is an integer from 1 to 10.

5. The organic EL device of claim 1, wherein the compound represented by Formula (1) is represented by one of Compounds 1 to 15:

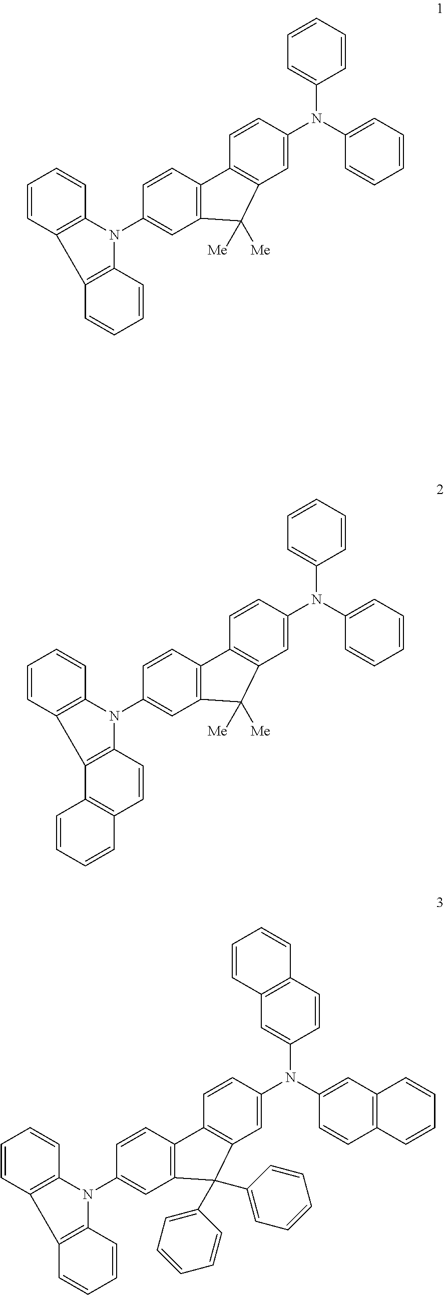 [SMILES: CC1(C)c2cc(N(c3ccccc3)c3ccccc3)ccc2-c2ccc(-n3c4ccccc4c4ccccc43)cc21 ; CC1(C)c2cc(N(c3ccccc3)c3ccccc3)ccc2-c2ccc(-n3c4ccccc4c4c5ccccc5ccc43)cc21 ; c1ccc(C2(c3ccccc3)c3cc(N(c4ccc5ccccc5c4)c4ccc5ccccc5c4)ccc3-c3ccc(-n4c5ccccc5c5ccccc54)cc32)cc1]

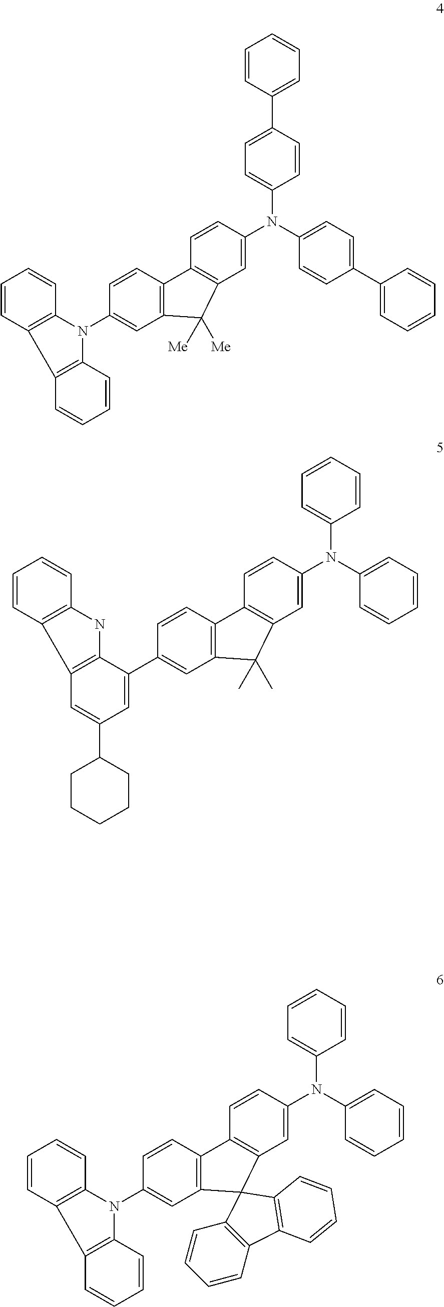 [SMILES: CC1(C)c2cc(N(c3ccc(-c4ccccc4)cc3)c3ccc(-c4ccccc4)cc3)ccc2-c2ccc(-n3c4ccccc4c4ccccc43)cc21 ; CC1(C)c2cc(-c3cc(C4CCCCC4)cc4c3[nH]c3ccccc34)ccc2-c2ccc(N(c3ccccc3)c3ccccc3)cc21 ; c1ccc(N(c2ccccc2)c2ccc3c(c2)C2(c4ccccc4-c4ccccc42)c2cc(-n4c5ccccc5c5ccccc54)ccc2-3)cc1]

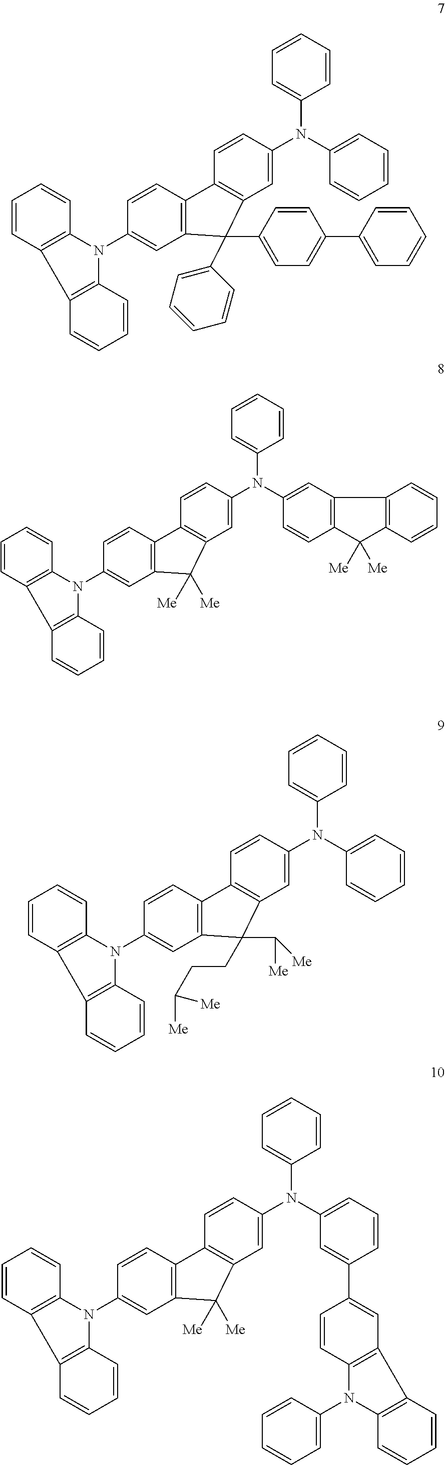 [SMILES: c1ccc(-c2ccc(C3(c4ccccc4)c4cc(N(c5ccccc5)c5ccccc5)ccc4-c4ccc(-n5c6ccccc6c6ccccc65)cc43)cc2)cc1 ; CC1(C)c2ccccc2-c2cc(N(c3ccccc3)c3ccc4c(c3)C(C)(C)c3cc(-n5c6ccccc6c6ccccc65)ccc3-4)ccc21 ; CC(C)CCC1(C(C)C)c2cc(N(c3ccccc3)c3ccccc3)ccc2-c2ccc(-n3c4ccccc4c4ccccc43)cc21 ; CC1(C)c2cc(N(c3ccccc3)c3cccc(-c4ccc5c(c4)c4ccccc4n5-c4ccccc4)c3)ccc2-c2ccc(-n3c4ccccc4c4ccccc43)cc21]

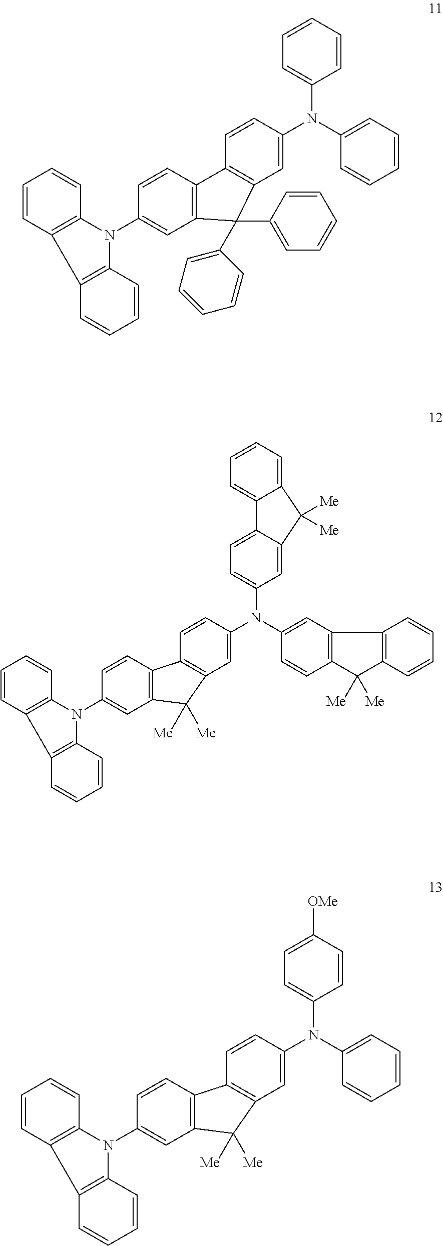 [SMILES: c1ccc(N(c2ccccc2)c2ccc3c(c2)C(c2ccccc2)(c2ccccc2)c2cc(-n4c5ccccc5c5ccccc54)ccc2-3)cc1 ; CC1(C)c2ccccc2-c2cc(N(c3ccc4c(c3)C(C)(C)c3ccccc3-4)c3ccc4c(c3)C(C)(C)c3cc(-n5c6ccccc6c6ccccc65)ccc3-4)ccc21 ; COc1ccc(N(c2ccccc2)c2ccc3c(c2)C(C)(C)c2cc(-n4c5ccccc5c5ccccc54)ccc2-3)cc1]

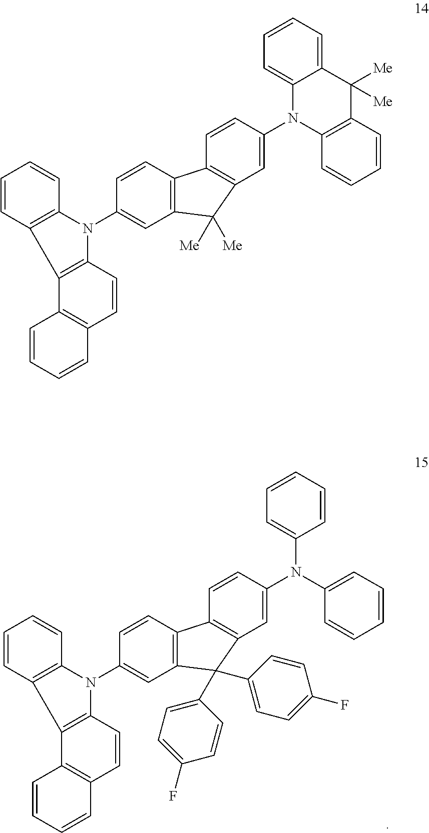 [SMILES: CC1(C)c2cc(N3c4ccccc4C(C)(C)c4ccccc43)ccc2-c2ccc(-n3c4ccccc4c4c5ccccc5ccc43)cc21 ; Fc1ccc(C2(c3ccc(F)cc3)c3cc(N(c4ccccc4)c4ccccc4)ccc3-c3ccc(-n4c5ccccc5c5c6ccccc6ccc54)cc32)cc1]

6. The organic EL device of claim 2, wherein the compound represented by Formula (2) is represented by one of Compounds 16 to 31:

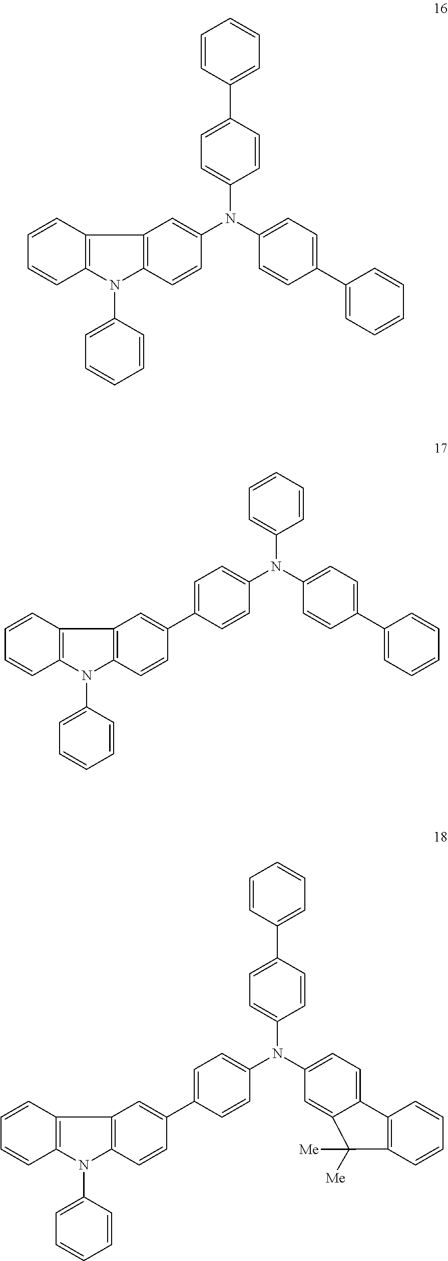 [SMILES: c1ccc(-c2ccc(N(c3ccc(-c4ccccc4)cc3)c3ccc4c(c3)c3ccccc3n4-c3ccccc3)cc2)cc1 ; c1ccc(-c2ccc(N(c3ccccc3)c3ccc(-c4ccc5c(c4)c4ccccc4n5-c4ccccc4)cc3)cc2)cc1 ; CC1(C)c2ccccc2-c2ccc(N(c3ccc(-c4ccccc4)cc3)c3ccc(-c4ccc5c(c4)c4ccccc4n5-c4ccccc4)cc3)cc21]

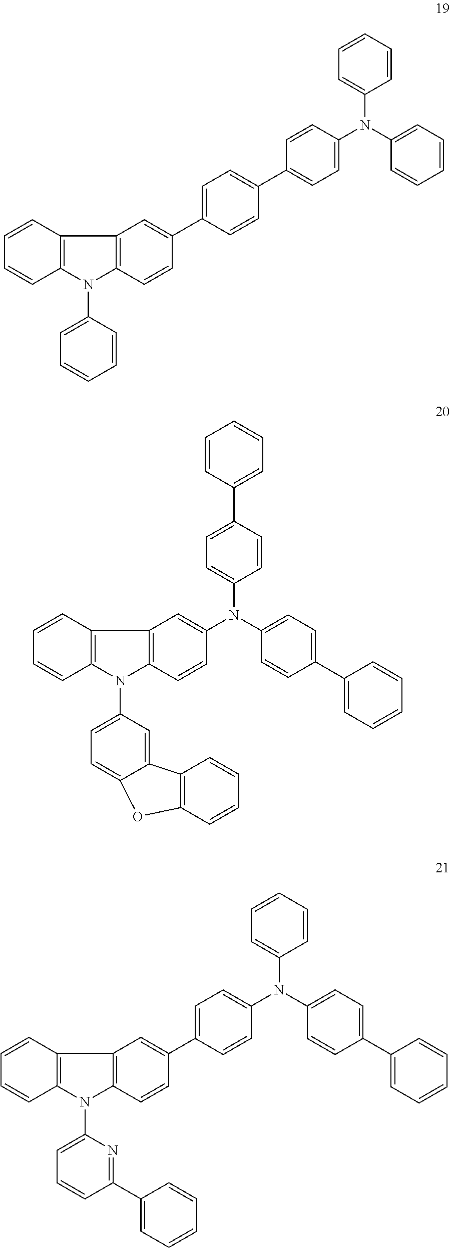 [SMILES: c1ccc(N(c2ccccc2)c2ccc(-c3ccc(-c4ccc5c(c4)c4ccccc4n5-c4ccccc4)cc3)cc2)cc1 ; c1ccc(-c2ccc(N(c3ccc(-c4ccccc4)cc3)c3ccc4c(c3)c3ccccc3n4-c3ccc4oc5ccccc5c4c3)cc2)cc1 ; c1ccc(-c2ccc(N(c3ccccc3)c3ccc(-c4ccc5c(c4)c4ccccc4n5-c4cccc(-c5ccccc5)n4)cc3)cc2)cc1]

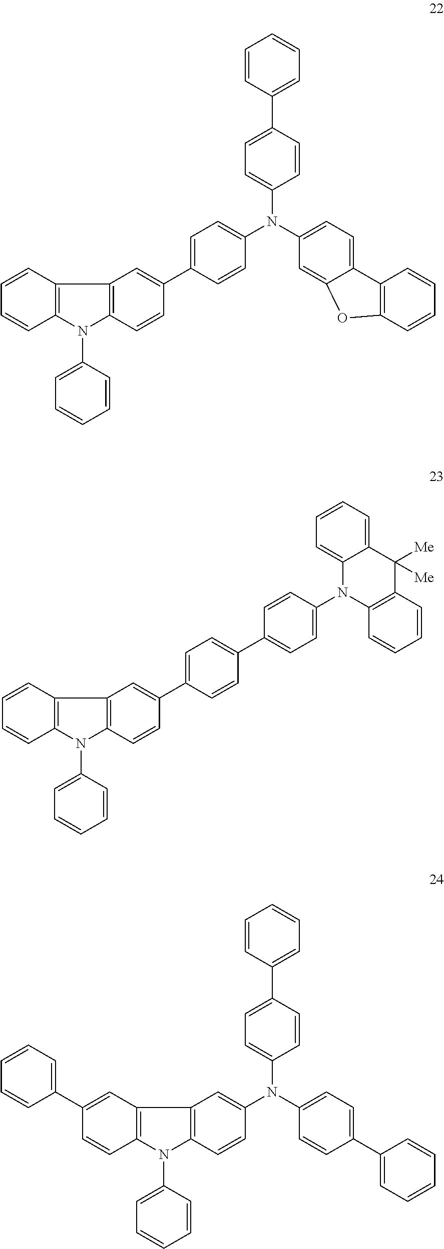 [SMILES: c1ccc(-c2ccc(N(c3ccc(-c4ccc5c(c4)c4ccccc4n5-c4ccccc4)cc3)c3ccc4c(c3)oc3ccccc34)cc2)cc1 ; CC1(C)c2ccccc2N(c2ccc(-c3ccc(-c4ccc5c(c4)c4ccccc4n5-c4ccccc4)cc3)cc2)c2ccccc21 ; c1ccc(-c2ccc(N(c3ccc(-c4ccccc4)cc3)c3ccc4c(c3)c3cc(-c5ccccc5)ccc3n4-c3ccccc3)cc2)cc1]

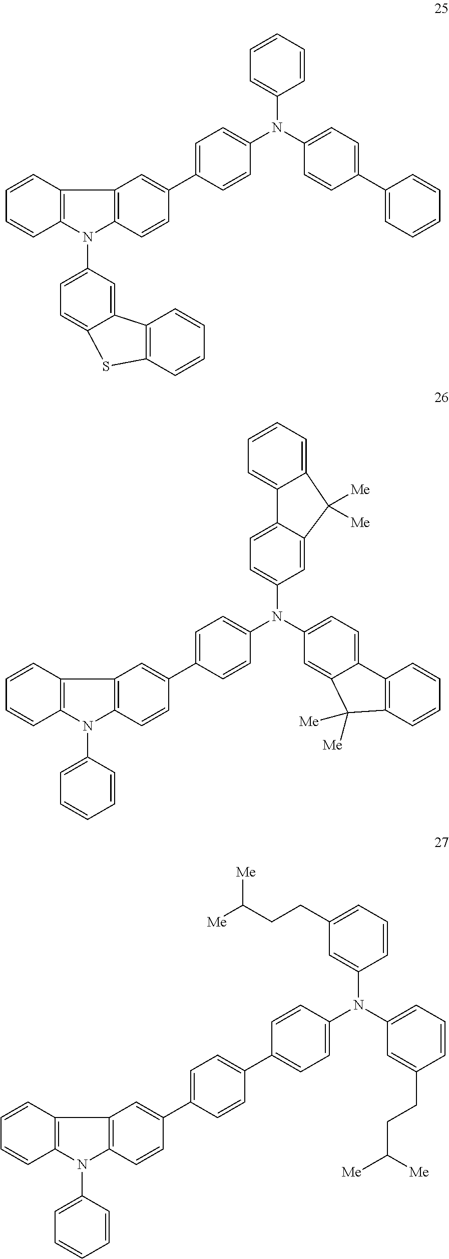 [SMILES: c1ccc(-c2ccc(N(c3ccccc3)c3ccc(-c4ccc5c(c4)c4ccccc4n5-c4ccc5sc6ccccc6c5c4)cc3)cc2)cc1 ; CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21 ; CC(C)CCc1cccc(N(c2ccc(-c3ccc(-c4ccc5c(c4)c4ccccc4n5-c4ccccc4)cc3)cc2)c2cccc(CCC(C)C)c2)c1]

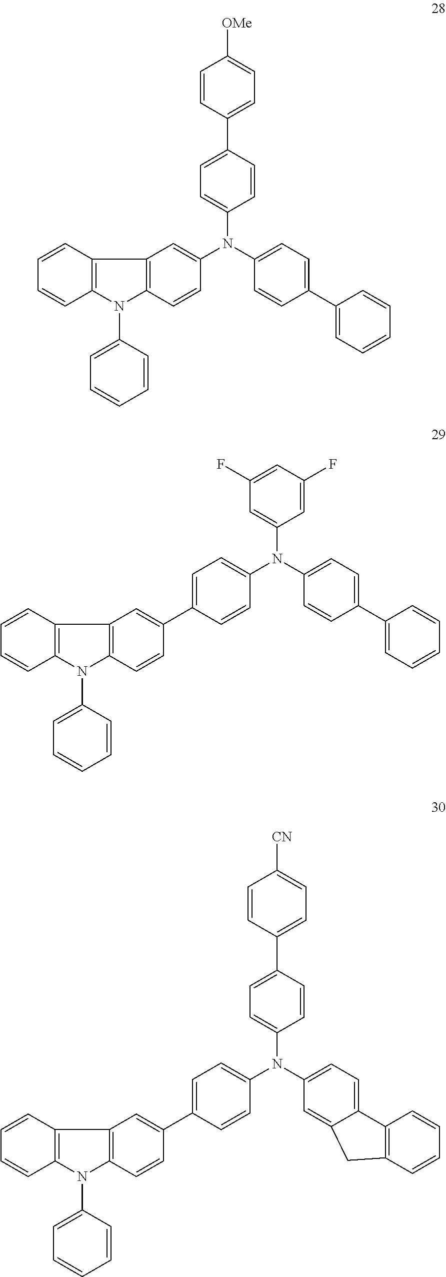 [SMILES: COc1ccc(-c2ccc(N(c3ccc(-c4ccccc4)cc3)c3ccc4c(c3)c3ccccc3n4-c3ccccc3)cc2)cc1 ; Fc1cc(F)cc(N(c2ccc(-c3ccccc3)cc2)c2ccc(-c3ccc4c(c3)c3ccccc3n4-c3ccccc3)cc2)c1 ; N#Cc1ccc(-c2ccc(N(c3ccc(-c4ccc5c(c4)c4ccccc4n5-c4ccccc4)cc3)c3ccc4c(c3)Cc3ccccc3-4)cc2)cc1]

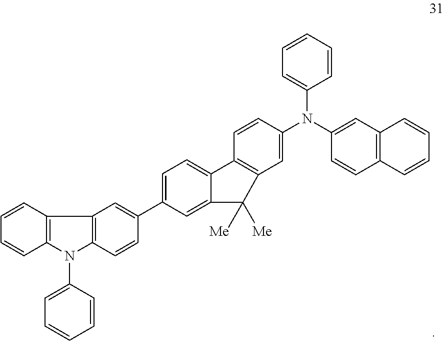 [SMILES: CC1(C)c2cc(-c3ccc4c(c3)c3ccccc3n4-c3ccccc3)ccc2-c2ccc(N(c3ccccc3)c3ccc4ccccc4c3)cc21]

7. The organic EL device of claim 3, wherein the hole transport compound represented by Formula (2) is represented by one of Compounds 16 to 31:

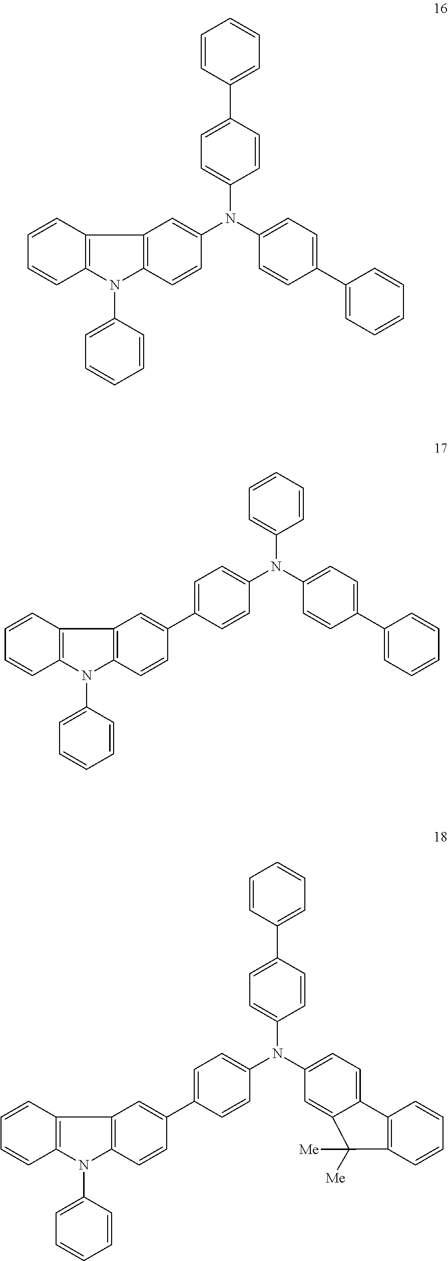 [SMILES: c1ccc(-c2ccc(N(c3ccc(-c4ccccc4)cc3)c3ccc4c(c3)c3ccccc3n4-c3ccccc3)cc2)cc1 ; c1ccc(-c2ccc(N(c3ccccc3)c3ccc(-c4ccc5c(c4)c4ccccc4n5-c4ccccc4)cc3)cc2)cc1 ; CC1(C)c2ccccc2-c2ccc(N(c3ccc(-c4ccccc4)cc3)c3ccc(-c4ccc5c(c4)c4ccccc4n5-c4ccccc4)cc3)cc21]

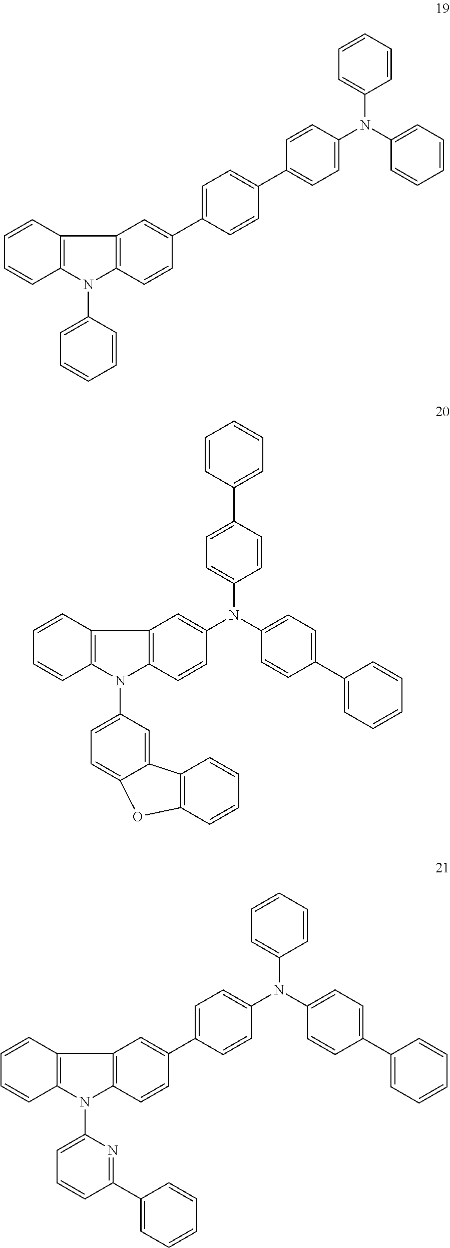 [SMILES: c1ccc(N(c2ccccc2)c2ccc(-c3ccc(-c4ccc5c(c4)c4ccccc4n5-c4ccccc4)cc3)cc2)cc1 ; c1ccc(-c2ccc(N(c3ccc(-c4ccccc4)cc3)c3ccc4c(c3)c3ccccc3n4-c3ccc4oc5ccccc5c4c3)cc2)cc1 ; c1ccc(-c2ccc(N(c3ccccc3)c3ccc(-c4ccc5c(c4)c4ccccc4n5-c4cccc(-c5ccccc5)n4)cc3)cc2)cc1]

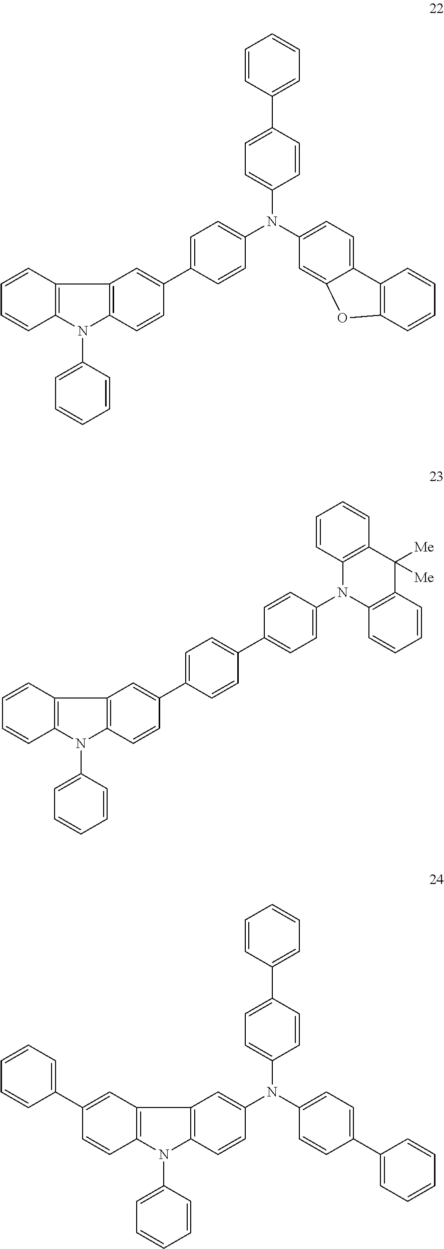 [SMILES: c1ccc(-c2ccc(N(c3ccc(-c4ccc5c(c4)c4ccccc4n5-c4ccccc4)cc3)c3ccc4c(c3)oc3ccccc34)cc2)cc1 ; CC1(C)c2ccccc2N(c2ccc(-c3ccc(-c4ccc5c(c4)c4ccccc4n5-c4ccccc4)cc3)cc2)c2ccccc21 ; c1ccc(-c2ccc(N(c3ccc(-c4ccccc4)cc3)c3ccc4c(c3)c3cc(-c5ccccc5)ccc3n4-c3ccccc3)cc2)cc1]

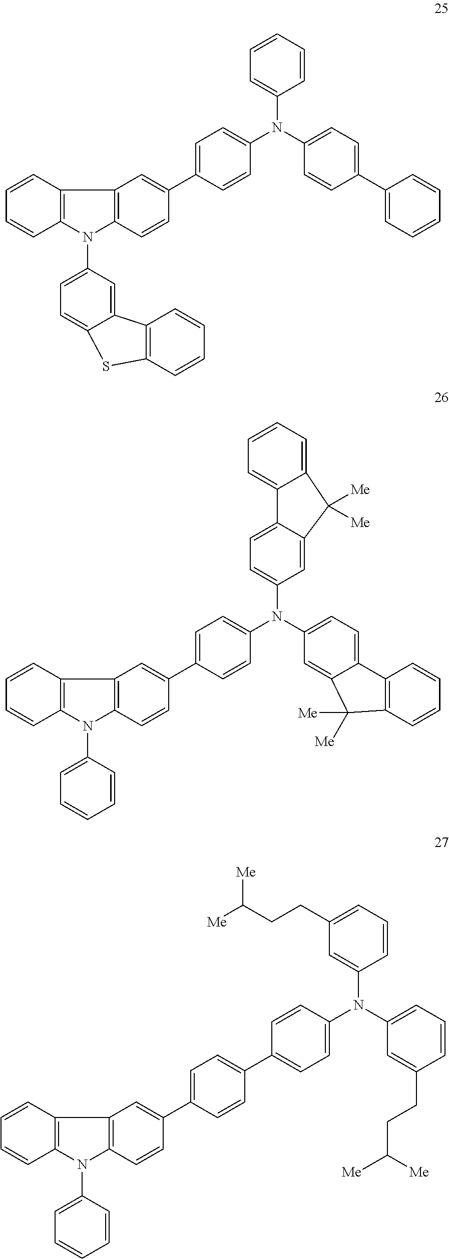 [SMILES: c1ccc(-c2ccc(N(c3ccccc3)c3ccc(-c4ccc5c(c4)c4ccccc4n5-c4ccc5sc6ccccc6c5c4)cc3)cc2)cc1 ; CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21 ; CC(C)CCc1cccc(N(c2ccc(-c3ccc(-c4ccc5c(c4)c4ccccc4n5-c4ccccc4)cc3)cc2)c2cccc(CCC(C)C)c2)c1]

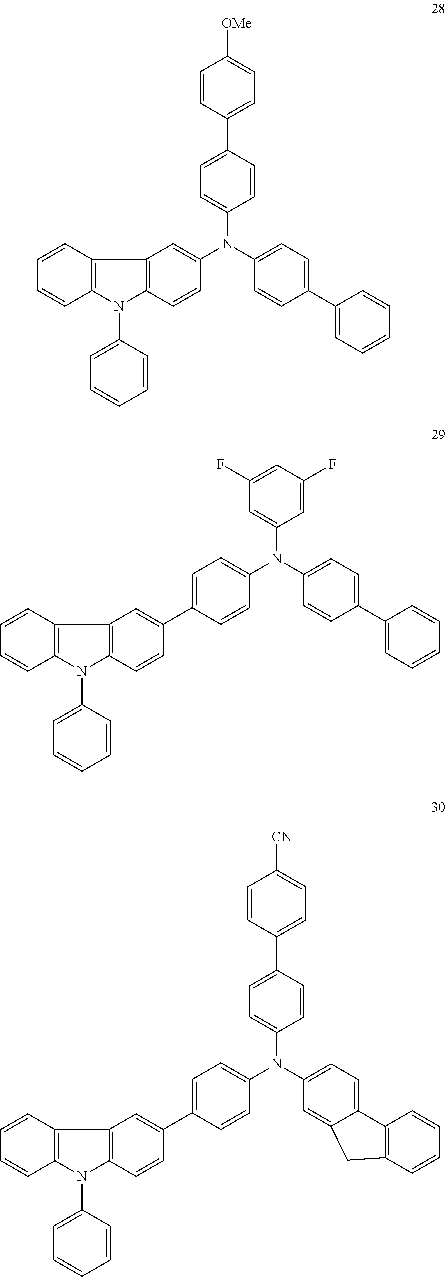 [SMILES: COc1ccc(-c2ccc(N(c3ccc(-c4ccccc4)cc3)c3ccc4c(c3)c3ccccc3n4-c3ccccc3)cc2)cc1 ; Fc1cc(F)cc(N(c2ccc(-c3ccccc3)cc2)c2ccc(-c3ccc4c(c3)c3ccccc3n4-c3ccccc3)cc2)c1 ; N#Cc1ccc(-c2ccc(N(c3ccc(-c4ccc5c(c4)c4ccccc4n5-c4ccccc4)cc3)c3ccc4c(c3)Cc3ccccc3-4)cc2)cc1]

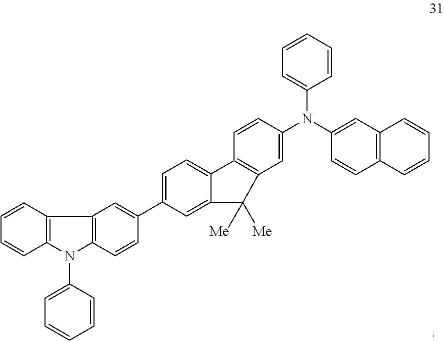 [SMILES: CC1(C)c2cc(-c3ccc4c(c3)c3ccccc3n4-c3ccccc3)ccc2-c2ccc(N(c3ccccc3)c3ccc4ccccc4c3)cc21]

8. The organic EL device of claim 4, wherein the compound represented by Formula (3) is represented by one of Compounds a-1 to a-12:

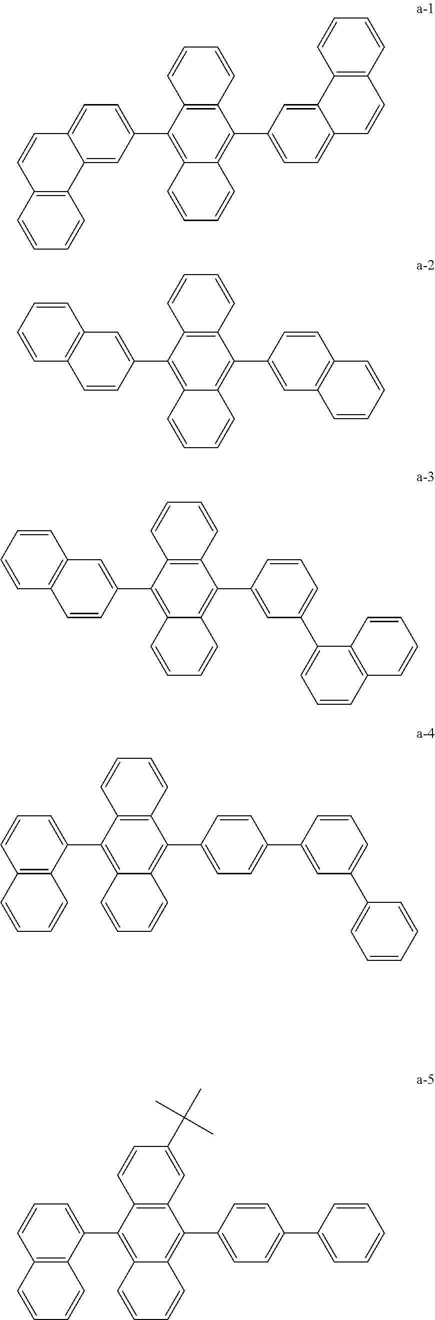

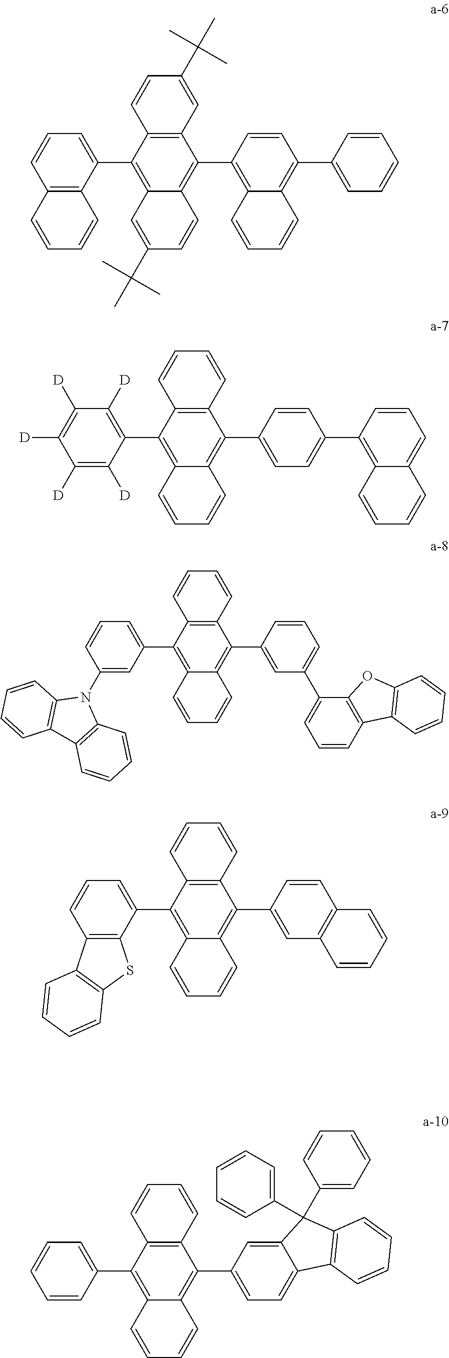

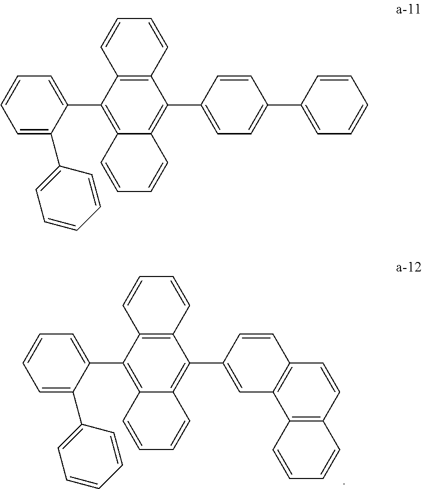

9. The organic EL device of claim 1, wherein the emission layer is configured to facilitate luminescence via a singlet excited state.]

10. An organic electroluminescent (EL) device comprising:
an anode,
a cathode,
an emission layer between the anode and the cathode, and
a laminate structure between the anode and the emission layer, the laminate structure comprising at least three layers, the at least three layers comprising:
a first layer comprising an electron accepting compound having a lowest unoccupied molecular orbital (LUMO) level from about −9.0 eV to about −4.0 eV as a main component; and
a second layer between the first layer and the emission layer, the second layer being adjacent to the emission layer and comprising a compound represented by Formula (1): 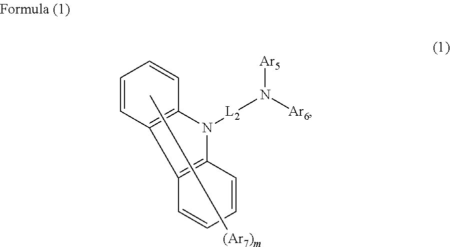
wherein, in Formula (1),
Ar₅, Ar₆ and Ar₇ are each independently selected from a substituted or unsubstituted aryl group having 6 to 30 carbon atoms for forming a ring, a substituted or unsubstituted heteroaryl group having 3 to 30 carbon atoms for forming a ring, an alkyl group having 1 to 10 carbon atoms, and an alkenyl group having 1 to 10 carbon atoms,
L₂ is a substituted or unsubstituted fluorenediyl group, and
m is an integer from 0 to 8.

11. The organic EL device of claim 10, wherein the first layer comprises the electron accepting compound in an amount equal to or greater than 50% by weight, based on the total weight of materials in the first layer.

12. The organic EL device of claim 10, wherein the at least three layers further comprise a third layer between the first layer and the second layer, the third layer comprising a compound represented by Formula (2): 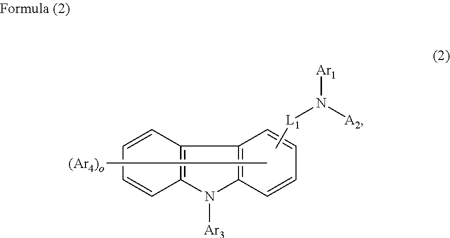
wherein, in Formula (2),
Ar₁, Ar₂ and Ar₃ are each independently selected from a substituted or unsubstituted aryl group having 6 to 30 carbon atoms for forming a ring, a substituted or unsubstituted heteroaryl group having 3 to 30 carbon atoms for forming a ring, an alkyl group having 1 to 10 carbon atoms, and an alkenyl group having 1 to 10 carbon atoms,
Ar₄ is selected from a substituted or unsubstituted aryl group having 6 to 30 carbon atoms for forming a ring, a substituted or unsubstituted heteroaryl group having 3 to 30 carbon atoms for forming a ring, an alkyl group having 1 to 10 carbon atoms, an alkenyl group having 1 to 10 carbon atoms, a deuterium atom, and a halogen atom,
L₁ is selected from a direct linkage, a substituted or unsubstituted arylene group having 6 to 30 carbon atoms for forming a ring, a heteroarylene group having 3 to 30 carbon atoms for forming a ring, and an alkylene group having 1 to 10 carbon atoms, and
o is an integer from 0 to 7.

13. The organic EL device of claim 10, wherein the emission layer comprises a compound represented by Formula (3): 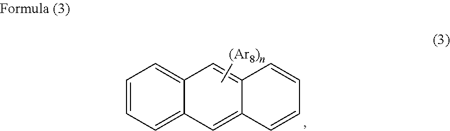
wherein, in Formula (3),
each Ar₈ is independently selected from a hydrogen atom, a deuterium atom, a substituted or unsubstituted aryl group having 6 to 30 carbon atoms for forming a ring, a substituted or unsubstituted heteroaryl group having 3 to 30 carbon atoms for forming a ring, and an alkyl group having 1 to 10 carbon atoms, and
n is an integer from 1 to 10.

14. The organic EL device of claim 10, wherein the compound represented by Formula (1) is represented by one of the following Compounds 1 to 15:

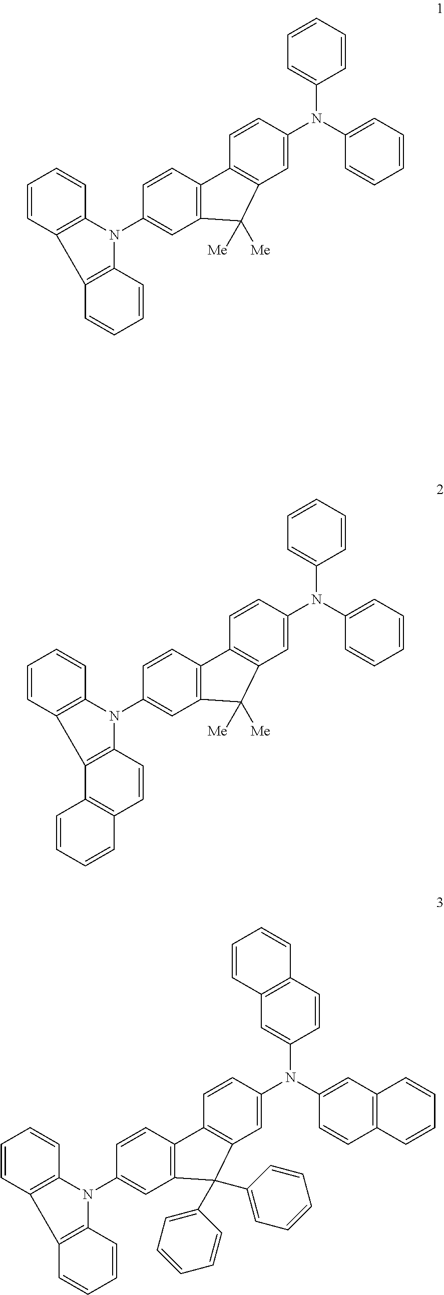 [SMILES: CC1(C)c2cc(N(c3ccccc3)c3ccccc3)ccc2-c2ccc(-n3c4ccccc4c4ccccc43)cc21 ; CC1(C)c2cc(N(c3ccccc3)c3ccccc3)ccc2-c2ccc(-n3c4ccccc4c4c5ccccc5ccc43)cc21 ; c1ccc(C2(c3ccccc3)c3cc(N(c4ccc5ccccc5c4)c4ccc5ccccc5c4)ccc3-c3ccc(-n4c5ccccc5c5ccccc54)cc32)cc1]

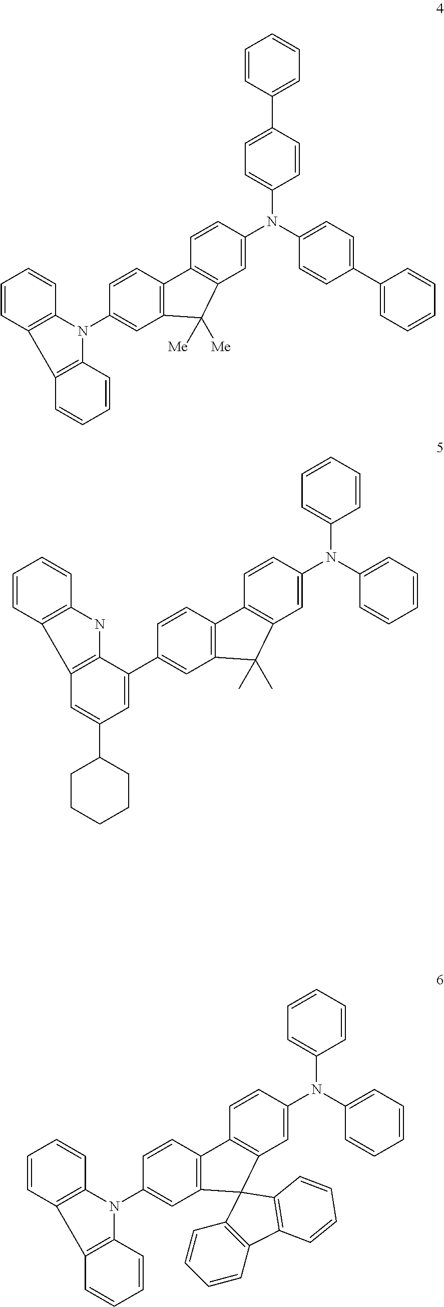 [SMILES: CC1(C)c2cc(N(c3ccc(-c4ccccc4)cc3)c3ccc(-c4ccccc4)cc3)ccc2-c2ccc(-n3c4ccccc4c4ccccc43)cc21 ; CC1(C)c2cc(-c3cc(C4CCCCC4)cc4c3[nH]c3ccccc34)ccc2-c2ccc(N(c3ccccc3)c3ccccc3)cc21 ; c1ccc(N(c2ccccc2)c2ccc3c(c2)C2(c4ccccc4-c4ccccc42)c2cc(-n4c5ccccc5c5ccccc54)ccc2-3)cc1]

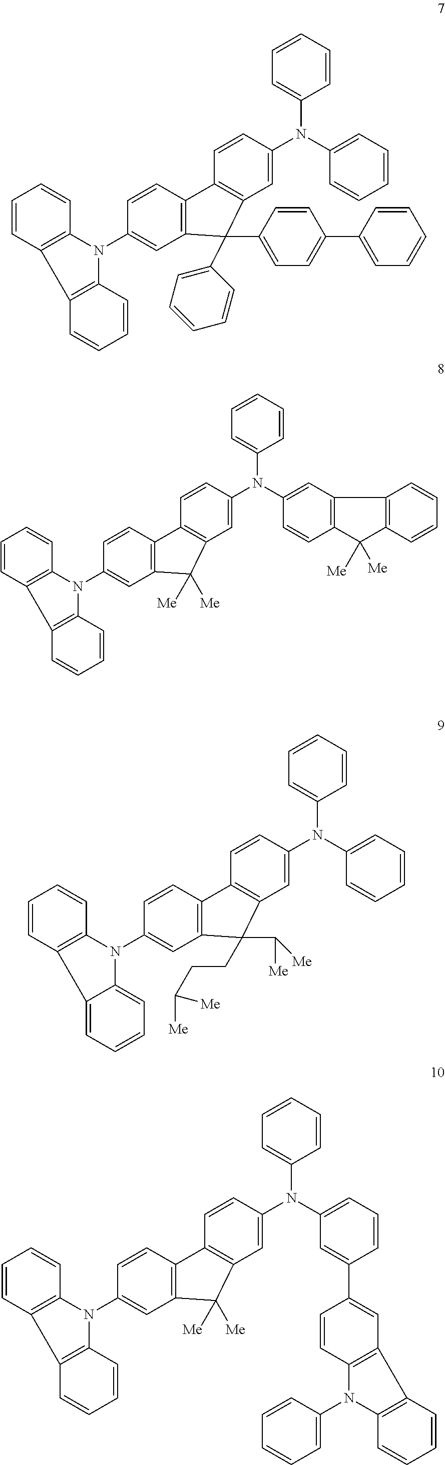 [SMILES: c1ccc(-c2ccc(C3(c4ccccc4)c4cc(N(c5ccccc5)c5ccccc5)ccc4-c4ccc(-n5c6ccccc6c6ccccc65)cc43)cc2)cc1 ; CC1(C)c2ccccc2-c2cc(N(c3ccccc3)c3ccc4c(c3)C(C)(C)c3cc(-n5c6ccccc6c6ccccc65)ccc3-4)ccc21 ; CC(C)CCC1(C(C)C)c2cc(N(c3ccccc3)c3ccccc3)ccc2-c2ccc(-n3c4ccccc4c4ccccc43)cc21 ; CC1(C)c2cc(N(c3ccccc3)c3cccc(-c4ccc5c(c4)c4ccccc4n5-c4ccccc4)c3)ccc2-c2ccc(-n3c4ccccc4c4ccccc43)cc21]

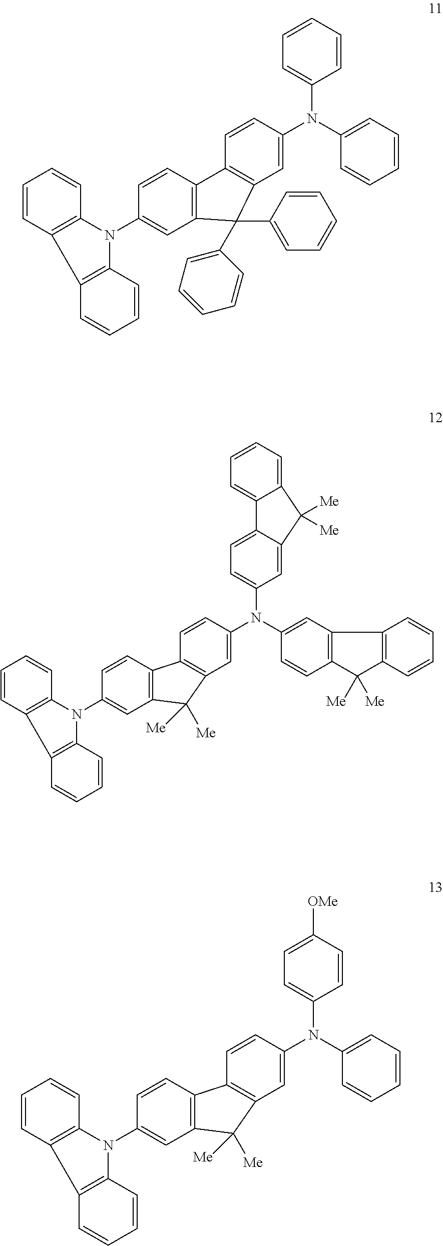 [SMILES: c1ccc(N(c2ccccc2)c2ccc3c(c2)C(c2ccccc2)(c2ccccc2)c2cc(-n4c5ccccc5c5ccccc54)ccc2-3)cc1 ; CC1(C)c2ccccc2-c2cc(N(c3ccc4c(c3)C(C)(C)c3ccccc3-4)c3ccc4c(c3)C(C)(C)c3cc(-n5c6ccccc6c6ccccc65)ccc3-4)ccc21 ; COc1ccc(N(c2ccccc2)c2ccc3c(c2)C(C)(C)c2cc(-n4c5ccccc5c5ccccc54)ccc2-3)cc1]

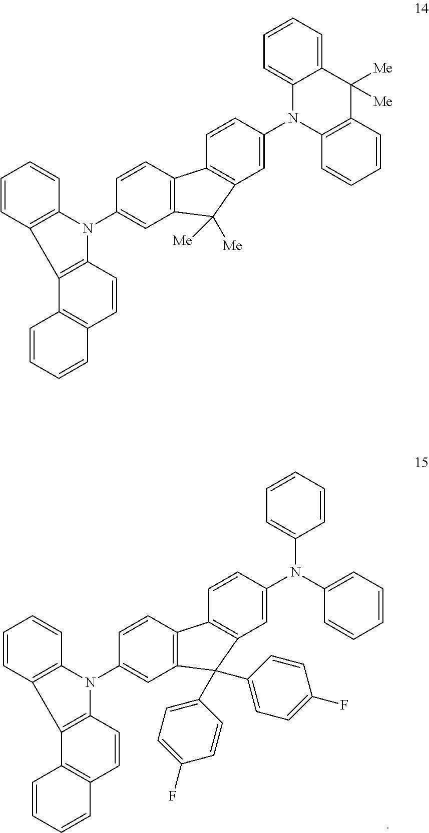 [SMILES: CC1(C)c2cc(N3c4ccccc4C(C)(C)c4ccccc43)ccc2-c2ccc(-n3c4ccccc4c4c5ccccc5ccc43)cc21 ; Fc1ccc(C2(c3ccc(F)cc3)c3cc(N(c4ccccc4)c4ccccc4)ccc3-c3ccc(-n4c5ccccc5c5c6ccccc6ccc54)cc32)cc1]

15. The organic EL device of claim 12, wherein the compound represented by Formula (2) is represented by one of Compounds 16 to 31:

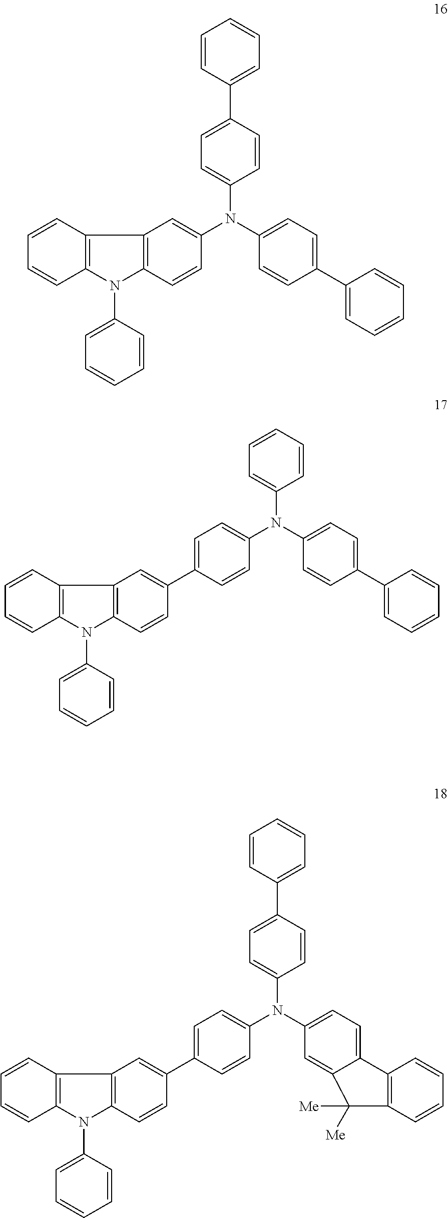 [SMILES: c1ccc(-c2ccc(N(c3ccc(-c4ccccc4)cc3)c3ccc4c(c3)c3ccccc3n4-c3ccccc3)cc2)cc1 ; c1ccc(-c2ccc(N(c3ccccc3)c3ccc(-c4ccc5c(c4)c4ccccc4n5-c4ccccc4)cc3)cc2)cc1 ; CC1(C)c2ccccc2-c2ccc(N(c3ccc(-c4ccccc4)cc3)c3ccc(-c4ccc5c(c4)c4ccccc4n5-c4ccccc4)cc3)cc21]

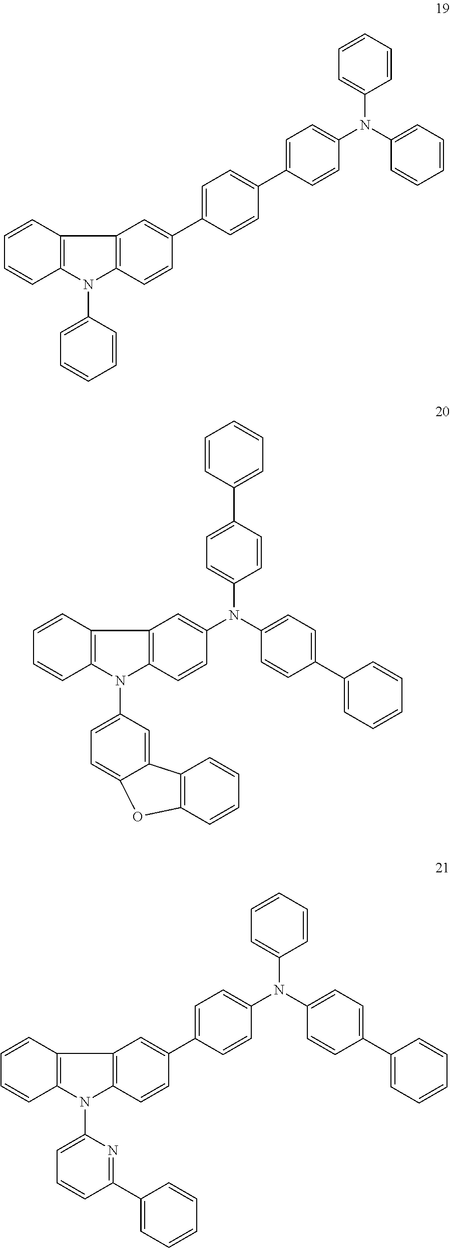 [SMILES: c1ccc(N(c2ccccc2)c2ccc(-c3ccc(-c4ccc5c(c4)c4ccccc4n5-c4ccccc4)cc3)cc2)cc1 ; c1ccc(-c2ccc(N(c3ccc(-c4ccccc4)cc3)c3ccc4c(c3)c3ccccc3n4-c3ccc4oc5ccccc5c4c3)cc2)cc1 ; c1ccc(-c2ccc(N(c3ccccc3)c3ccc(-c4ccc5c(c4)c4ccccc4n5-c4cccc(-c5ccccc5)n4)cc3)cc2)cc1]

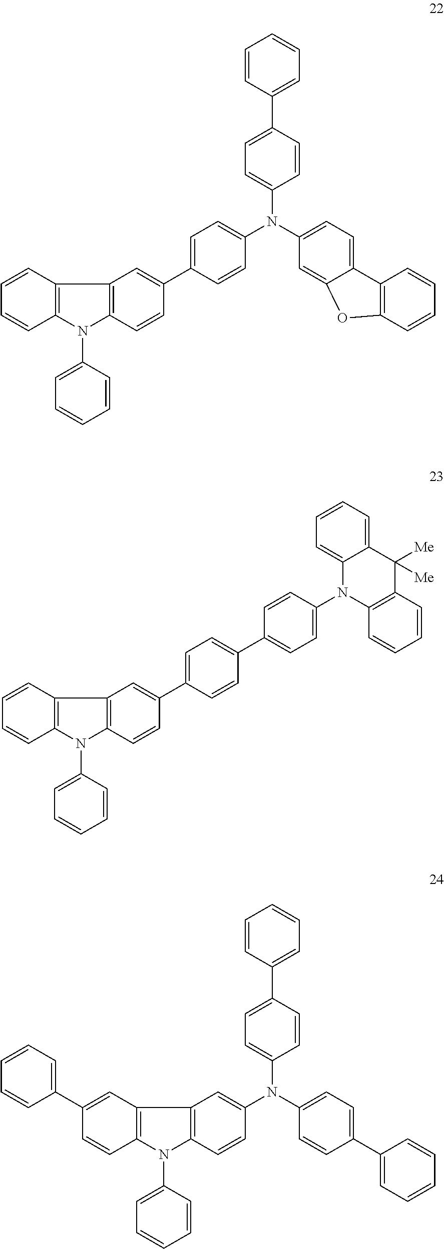 [SMILES: c1ccc(-c2ccc(N(c3ccc(-c4ccc5c(c4)c4ccccc4n5-c4ccccc4)cc3)c3ccc4c(c3)oc3ccccc34)cc2)cc1 ; CC1(C)c2ccccc2N(c2ccc(-c3ccc(-c4ccc5c(c4)c4ccccc4n5-c4ccccc4)cc3)cc2)c2ccccc21 ; c1ccc(-c2ccc(N(c3ccc(-c4ccccc4)cc3)c3ccc4c(c3)c3cc(-c5ccccc5)ccc3n4-c3ccccc3)cc2)cc1]

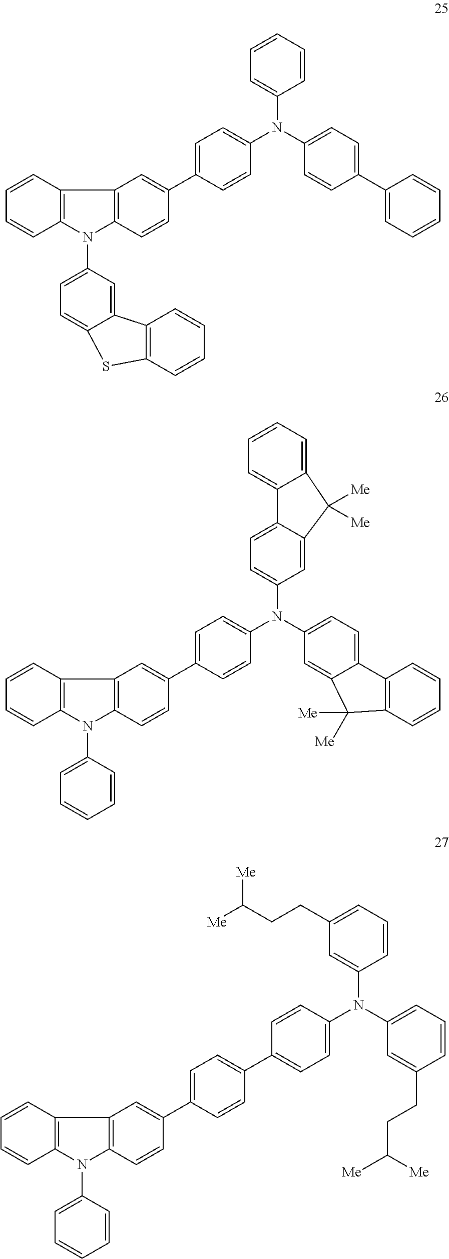 [SMILES: c1ccc(-c2ccc(N(c3ccccc3)c3ccc(-c4ccc5c(c4)c4ccccc4n5-c4ccc5sc6ccccc6c5c4)cc3)cc2)cc1 ; CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21 ; CC(C)CCc1cccc(N(c2ccc(-c3ccc(-c4ccc5c(c4)c4ccccc4n5-c4ccccc4)cc3)cc2)c2cccc(CCC(C)C)c2)c1]

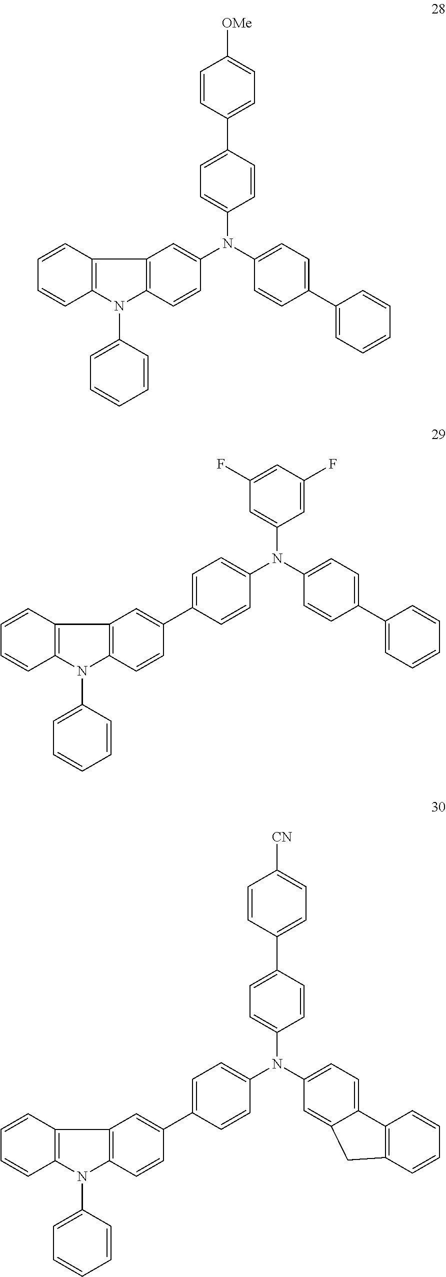 [SMILES: COc1ccc(-c2ccc(N(c3ccc(-c4ccccc4)cc3)c3ccc4c(c3)c3ccccc3n4-c3ccccc3)cc2)cc1 ; Fc1cc(F)cc(N(c2ccc(-c3ccccc3)cc2)c2ccc(-c3ccc4c(c3)c3ccccc3n4-c3ccccc3)cc2)c1 ; N#Cc1ccc(-c2ccc(N(c3ccc(-c4ccc5c(c4)c4ccccc4n5-c4ccccc4)cc3)c3ccc4c(c3)Cc3ccccc3-4)cc2)cc1]

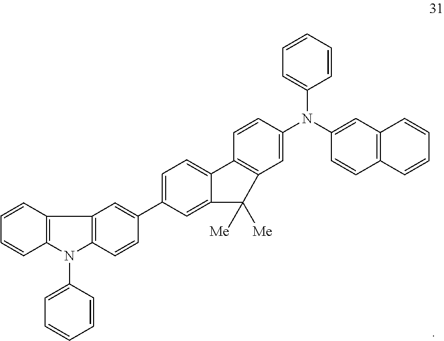 [SMILES: CC1(C)c2cc(-c3ccc4c(c3)c3ccccc3n4-c3ccccc3)ccc2-c2ccc(N(c3ccccc3)c3ccc4ccccc4c3)cc21]

16. The organic EL device of claim 13, wherein the compound represented by Formula (3) is selected from Compounds a-1 to a-12:

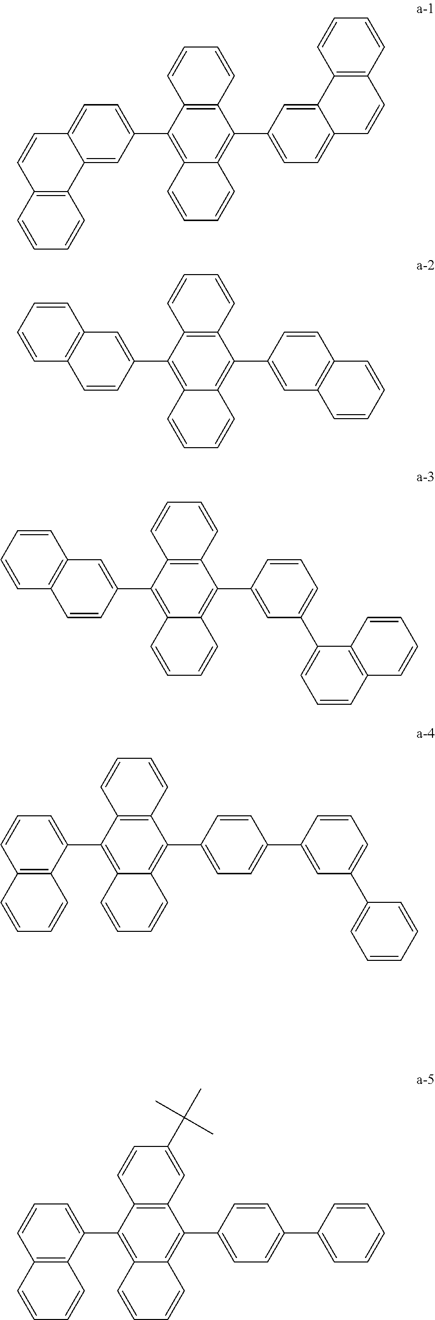

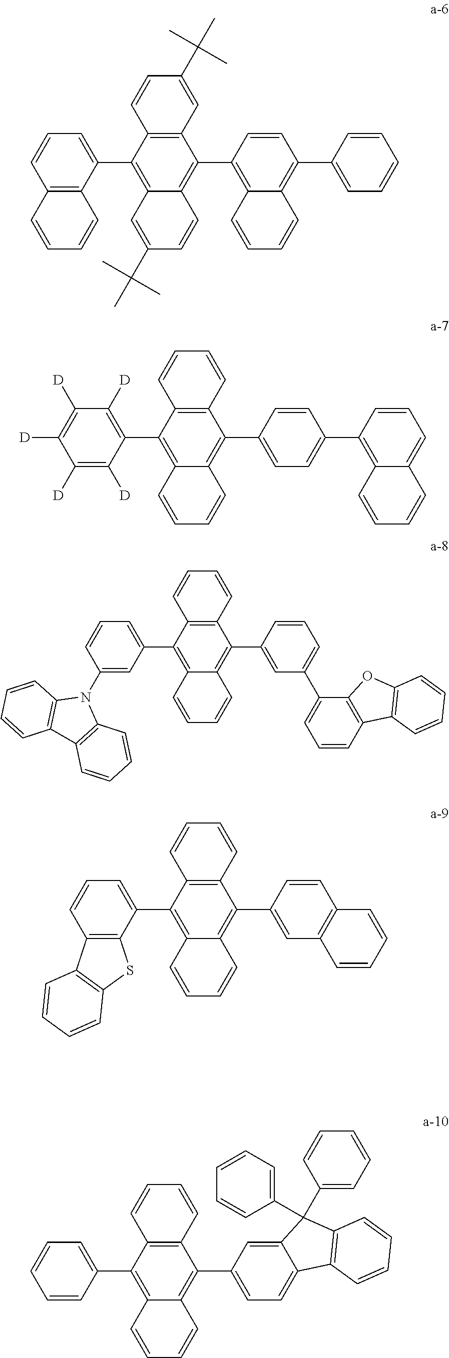

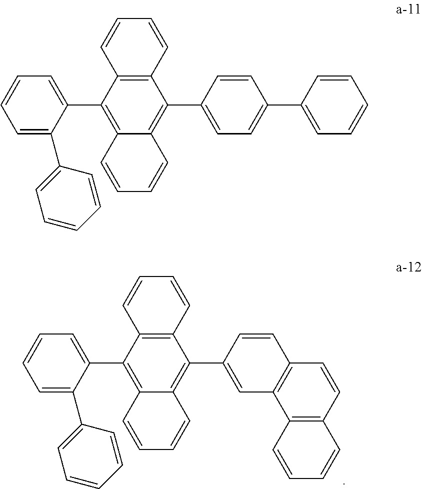

17. The organic EL device of claim 10, wherein the emission layer is configured to facilitate luminescence via a singlet excited state.
